(19) United States
(12) Patent Application Publication
(10) Pub. No.: US 2015/0127985 A1
(43) Pub. Date: May 7, 2015

(54) INFORMATION PROCESSING APPARATUS AND ACCESS CONTROL METHOD

(71) Applicant: FUJITSU LIMITED, Kawasaki-shi (JP)

(72) Inventor: Kunihito ONOUE, Kawasaki (JP)

(21) Appl. No.: 14/576,620

(22) Filed: Dec. 19, 2014

Related U.S. Application Data
(63) Continuation of application No. PCT/JP2012/067078, filed on Jul. 4, 2012.

(51) Int. Cl. G11C 29/10

(52) U.S. Cl. CPC G11C 29/10
USPC 714/33

(57) ABSTRACT

A detection unit detects access status of an information recording device and forms the detected access status into access records at predetermined time intervals. A generation unit generates history information from the access records that have been formed over a predetermined period. A control unit selects an access record that has a predetermined relationship with the current time, out of the history information. A control unit determines when to start a diagnosis of the information recording device, assuming that the selected access record represents the current access status of the device. Specifically, the control unit instructs a diagnosis unit to start a diagnosis when the selected access record suggests that the diagnosis would not impose an excessive load on the information recording device.

### CROSS-REFERENCE TO RELATED APPLICATION

This application is a continuation application of International Application PCT/JP2012/067078 filed on Jul. 4, 2012 which designated the U.S., the entire contents of which are incorporated herein by reference.

### FIELD

The embodiments discussed herein relates to an information processing apparatus and an access control method.

### BACKGROUND

Magnetic disk devices are widely used as high-speed large-capacity data storage for computers. (This description refers to such storage devices as information recording devices.) To ensure the reliability of stored data, a computer has a diagnostic function to detect a failure in its built-in or external magnetic disk devices. This diagnostic function may, however, contend with an application running on the computer because both of them make access to magnetic disk devices. An increased access load due to the diagnostic function would render the magnetic disk devices less responsive to the application. One possible countermeasure is to monitor the access status of magnetic disk devices and initiate a diagnosis when their access load is small.

See, for example, Japanese Laid-open Patent Publication Nos. 5-74059, 2001-5616, 2008-27240, and 2009-151519.

In monitoring the access load on magnetic disk devices, some amount of time is spent to determine their current load level. This load monitoring time is, however, merely a waiting time during which the computer is unable to start diagnosing magnetic disk devices. The diagnosis starts after the waiting time is over, but it could be interrupted by an excessive increase in the access load. Such intermittent execution of diagnosis is inefficient.

### SUMMARY

According to one aspect of the embodiments, there is provided an information processing apparatus including a processor configured to perform a procedure including: detecting access status of an information recording device and forming the detected access status into access records at predetermined time intervals; generating history information from the access records that have been formed over a predetermined period; selecting at least one of the access records that has a predetermined relationship with a current time, out of the history information; and controlling a start of a diagnosis of the information recording device on the basis of the selected access record.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an exemplary configuration and an exemplary process of an information processing apparatus of a first embodiment;

FIG. 2 illustrates an exemplary configuration of an information processing system of a second embodiment;

FIG. 3 illustrates an exemplary configuration of host computers of the second embodiment;

FIG. 4 illustrates an exemplary configuration of an access management computer of the second embodiment;

FIG. 5 illustrates an exemplary hardware configuration of host computers of the second embodiment;

FIG. 6 is a flowchart of an access history collecting process of the second embodiment;

FIG. 7 illustrates an example of access history data of the second embodiment;

FIG. 8 is a flowchart of an access analyzing process of the second embodiment;

FIG. 9 illustrates an example of an access analyzing data of the second embodiment;

FIG. 10 is a flowchart of a request responding process of the second embodiment;

FIG. 11 illustrates an example of an access database (an index) of the second embodiment;

FIG. 12 illustrates an example of an access database (access analyzing data) of the second embodiment;

FIG. 13 illustrates an example of diagnosis control data of the second embodiment;

FIGS. 14 and 15 are a flowchart of a diagnosis control process (1) of the second embodiment;

FIGS. 16 and 17 are a flowchart of a diagnosis control process (2) of the second embodiment;

FIGS. 18 and 19 are a flowchart of a diagnosis control process (3) of a third embodiment;

FIGS. 20 and 21 are a flowchart of a diagnosis control process (4) of the third embodiment;

FIGS. 22 and 23 are a flowchart of a diagnosis control process (5) of a fourth embodiment;

FIGS. 24 and 25 are a flowchart of a diagnosis control process (6) of the fourth embodiment;

FIG. 26 is a flowchart of a variation of the diagnosis control process (5) of the fourth embodiment;

FIGS. 27 to 34 illustrate examples of a diagnosis control data selection user interface of the fourth embodiment;

FIG. 35 illustrates an example of diagnosis control data of a fifth embodiment;

FIG. 36 is a flowchart of a diagnosis control process (7) of the fifth embodiment; and

FIG. 37 illustrates an exemplary configuration of host computers of a sixth embodiment.

### DESCRIPTION OF EMBODIMENTS

Several embodiments will be described below with reference to the accompanying drawings, wherein like reference numerals refer to like elements throughout.

### First Embodiment

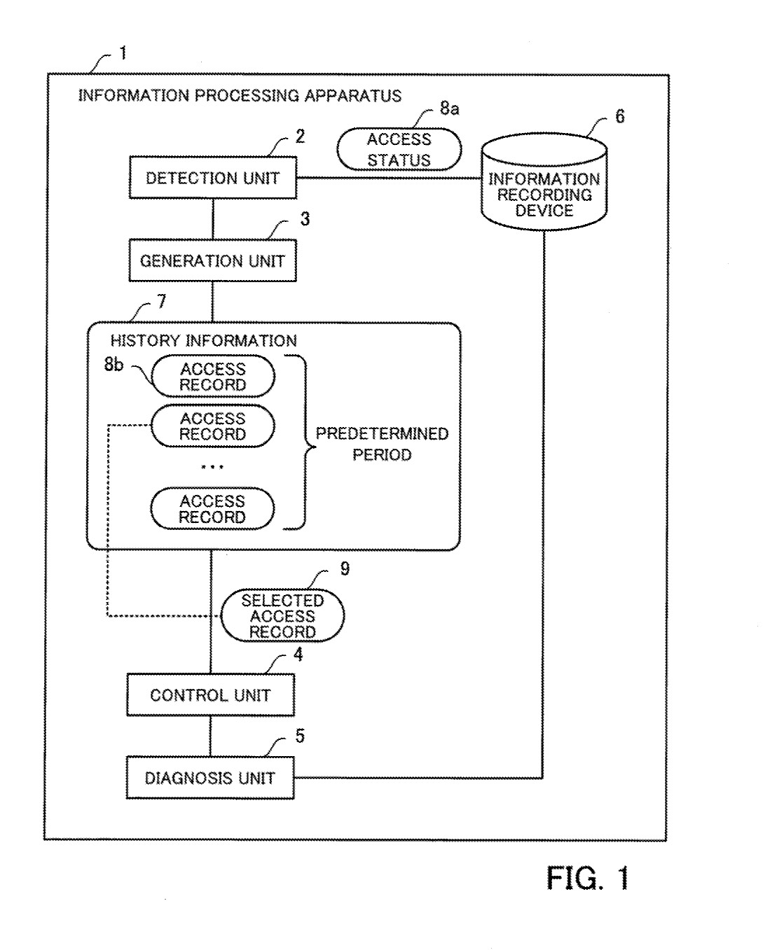

A first embodiment will now be described below with reference to FIG. 1. Specifically, FIG. 1 illustrates an exemplary configuration and an exemplary process of an information processing apparatus of the first embodiment.

The illustrated information processing apparatus 1 diagnoses an information recording device 6 to detect a failure of its information recording area. The information processing apparatus 1 controls when to perform this diagnosis in a manner to reduce the expected performance degradation of other processes (e.g., business applications) that make access to the information recording device 6 for other purposes than diagnosis.

The information recording device 6 is, for example, a hard disk drive (HDD: magnetic disk device), a solid state drive (SSD), or other storage devices capable of reading and writing information. Note that the information recording device 6 may be either integrated in the information processing apparatus 1, or placed outside the information processing apparatus 1. Also, the information recording device 6 may be a single storage device, or may be a plurality of storage devices configured as a RAID (Redundant Array of Inexpensive Disks) system, for example.

The information processing apparatus 1 includes a detection unit 2, a generation unit 3, a control unit 4, and a diagnosis unit 5. The detection unit 2 detects access status 8a of the information recording device 6 at predetermined time intervals. More specifically, the detection unit 2 monitors access operations made to the information recording device 6, and acquires its access status 8a at predetermined time intervals (for example, every minute). Note that this monitoring excludes access operations performed for the purpose of diagnosis. The access status 8a is some pieces of information that indicate the statistics of access to the information recording device 6, such as the number of access operations, the amount of data transmitted in those operations, data transmission rates, and distinctions between read and write.

The generation unit 3 generates history information 7 from a plurality of records of access status that the detection unit 2 detected and transmitted during a predetermined period. For example, the predetermined period may be fixed to, for example, twenty-four hours, or may be varied with irregular events.

The history information 7 contains access records 8b collected during the predetermined period noted above. The history information 7 is stored in, for example, a ring buffer whose content is updated by overwriting a new access record on an old access record. The history information 7 may be held inside the information processing apparatus 1, or may be held in an external device.

The access status 8a represents the current statistical status of access being made to the information recording device 6, which is detected by the detection unit 2. The access records 8b, on the other hand, represent the past statistical status of the same, collected and held as a set of history information 7.

The control unit 4 searches the history information 7 to select one of those access records 8b that has a predetermined relationship with the current time. The term “predetermined relationship” refers to a relationship with which the actual access status at the current time is expected to be the same as one of the access records in the history information 7. For example, when access operations from an application to the information recording device 6 have a twenty-four hour periodicity, an access record 8b obtained twenty-four hours earlier than the current time point is construed to be in the “predetermined relationship” with the current access status of the information recording device 6.

The control unit 4 controls when to activate the diagnosis unit 5 to start a diagnosis of the information recording device 6 based on the selected access record 9. That is, the control unit 4 regards the selected access record 9 as representing the current access status of the information recording device 6, and if its access load is reasonably small enough to initiate diagnosis start control, it instructs the diagnosis unit 5 to start a diagnosis of the information recording device 6.

The diagnosis unit 5 executes a diagnosis of the information recording device 6 upon instruction from the control unit 4. The diagnosis unit 5 may also halt and restart the ongoing diagnosis of the information recording device 6 when so instructed from the control unit 4.

In this way, the information processing apparatus 1 starts a diagnosis of the information recording device 6, without monitoring the current access status 8a of the information recording device 6. That is, the information processing apparatus 1 does not need to spend time for monitoring access status of the information recording device 6, before starting its diagnosis. If the detection unit 2 was configured to detect the current access status 8a before a diagnosis, the information processing apparatus 1 would need to wait for a predetermined unit time for detection of access status. The proposed information processing apparatus 1 can start a diagnosis of the information recording device 6 without such waiting time. Also, the proposed techniques increase the possibility of starting a diagnosis right at the time when the information recording device 6 can safely avoid excessive load. This means that an ongoing diagnosis is less likely to stop in the middle of its execution. For these reasons, the information processing apparatus 1 efficiently diagnoses magnetic disk devices and other information recording media.

### Second Embodiment

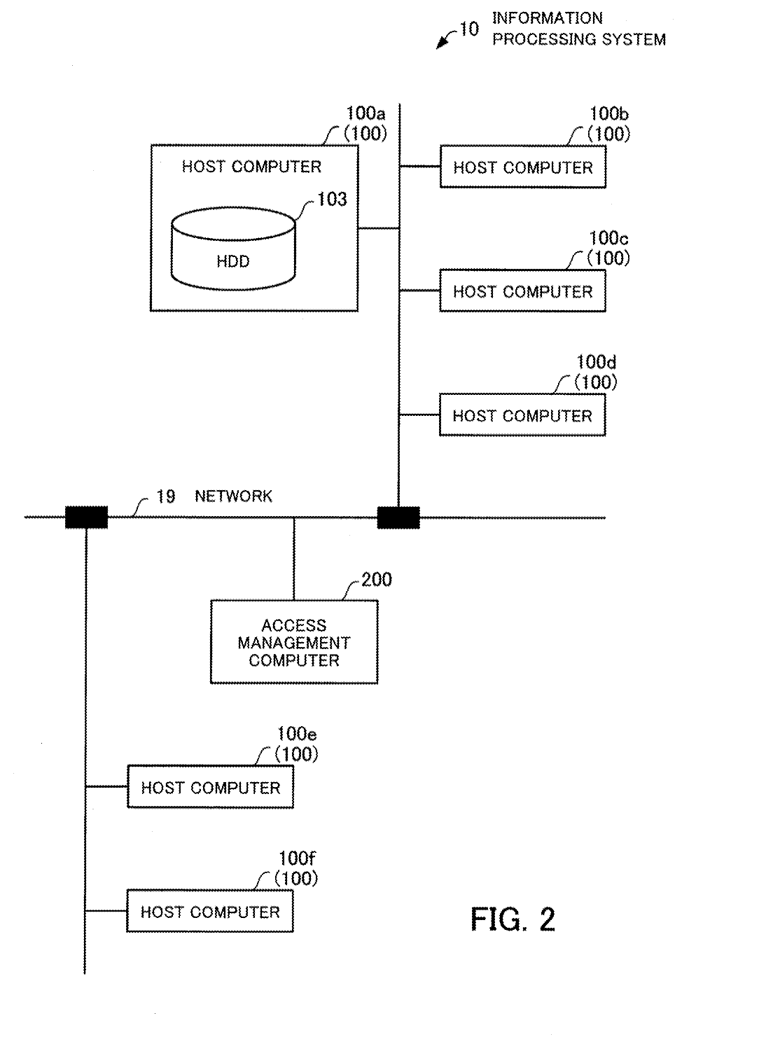

A second embodiment will now be described below with reference to FIG. 2 illustrating an information processing system. FIG. 2 illustrates an exemplary configuration of an information processing system of the second embodiment.

The illustrated information processing system 10 is designed to provide a certain class of information processing services. The information processing system 10 includes a plurality of host computers 100 (100a, 100b, . . . ) and an access management computer 200, which communicate with each other via a network 19.

The host computers 100 are each equipped with or connected to an HDD 103 and diagnose their HDDs 103 at appropriate times. Also, the host computers 100 analyze access status of the HDDs 103. The access management computer 200 collects records of access status (access records) from the host computers 100, and stores them in a database. The host computers 100 diagnose their HDDs 103 on the basis of the access records that the access management computer 200 stores in the database.

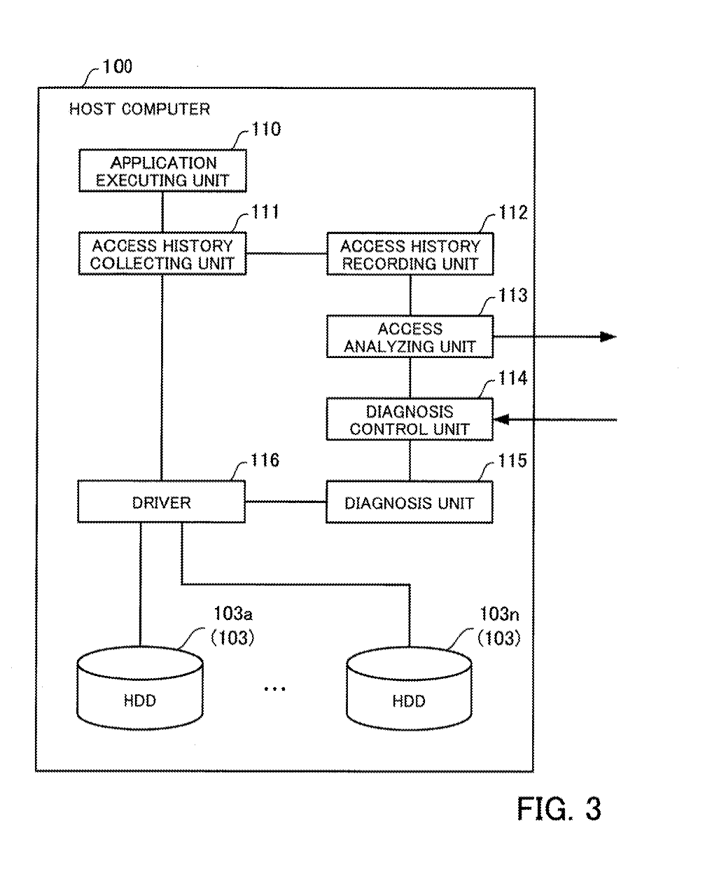

The following description explains a configuration of host computers of the second embodiment with reference to FIG. 3. FIG. 3 illustrates an exemplary configuration of host computers of the second embodiment.

The illustrated host computer 100 is equipped with a plurality of HDDs 103 (HDD 103a to HDD 103n), which are to be diagnosed, and accesses these HDDs 103 upon request from applications. The HDDs 103 may be configured as a storage system in which a plurality of HDDs 103a to 103n are organized as RAID disks. Alternatively, it is also possible to build a host computer 100 with a single HDD 103.

The host computer 100 includes an application executing unit 110, an access history collecting unit 111, an access history recording unit 112, an access analyzing unit 113, a diagnosis control unit 114, a diagnosis unit 115, and a driver 116, besides the HDDs 103 (103a, 103n) noted above.

The application executing unit 110 executes an application that generates access requests to the HDDs 103. For example, the application executing unit 110 executes a business application that implements the user's business operation on the host computer 100.

The access history collecting unit 111 collects access history data representing a log of access to HDDs 103 that the application executing unit 110 has made. More specifically, the access history collecting unit 111 accepts access requests to HDDs 103 (HDD access commands) from the application executing unit 110 to collect statistics of such access operations as an access history, while forwarding the access requests to the driver 116 for the HDDs 103. The driver 116 executes a specific command process in accordance with each received access request and returns a response from the HDDs 103 to the access history collecting unit 111. The application executing unit 110 receives this response via the access history collecting unit 111. In this way, the access history collecting unit 111 monitors access requests issued from the application executing unit 110 to the HDDs 103, as well as responses from the HDDs 103, to collect access histories. Note that the access history collecting unit 111 performs the above things for the plurality of HDDs on an individual basis.

The access history recording unit 112 temporarily records the collected access history in memory. The access analyzing unit 113 analyzes the access history recorded by the access history recording unit 112. For example, the access analyzing unit 113 calculates access frequency and data transmission rate of access made to the HDDs 103 during each predetermined time interval from the access history in that interval. The access analyzing unit 113 notifies the access management computer 200 of the calculated access frequency and data transmission rate of each time interval. This analysis result is referred to as access analyzing data. Also, the access analyzing unit 113 notifies the access management computer 200 of the access history of each HDD 103 in addition to the analysis result of the same.

The access management computer 200 manages access histories of HDDs 103 that are diagnosed by a plurality of host computers 100 (100a, 100b, . . . , 100f). The access management computer 200 provides those host computers 100 with service functions as an access database.

In this way, the access analyzing unit 113 quantitatively evaluates statistics of access operations on each HDD 103 at predetermined time intervals. The access analyzing unit 113 supplies the access management computer 200 with an access history of each HDD 103 and its analysis result.

The diagnosis control unit 114 controls activation of the diagnosis unit 115 that executes a diagnosis of HDDs 103. That is, the diagnosis control unit 114 controls the diagnosis unit 115 as to the decisions on, for example, which HDD 103 to diagnose, when to start its diagnosis, and whether to halt or restart the diagnosis. Other control decisions may include, for example, suppression, recovery, and termination of diagnoses. The diagnosis control unit 114 controls the diagnosis unit 115 on the basis of access histories of HDDs 103 and their analysis results acquired from the access database managed by the access management computer 200, as well as analysis results obtained from the access analyzing unit 113.

The diagnosis unit 115 executes a diagnosis of HDDs 103 under the control of the diagnosis control unit 114. For example, the diagnosis unit 115 evaluates the execution result of read commands for reading out recorded data on the HDDs 103. The diagnosis unit 115 diagnoses the entire data from the beginning to the end of logical block addressing (LBA) space of each HDD 103 under test. Note that the second embodiment is not limited to any specific order of reading data in HDDs 103 as long as the diagnosis covers a specified address range. For example, the diagnosis unit 115 may access the HDDs 103 in ascending order, descending order, random order, or any other order that is planned previously.

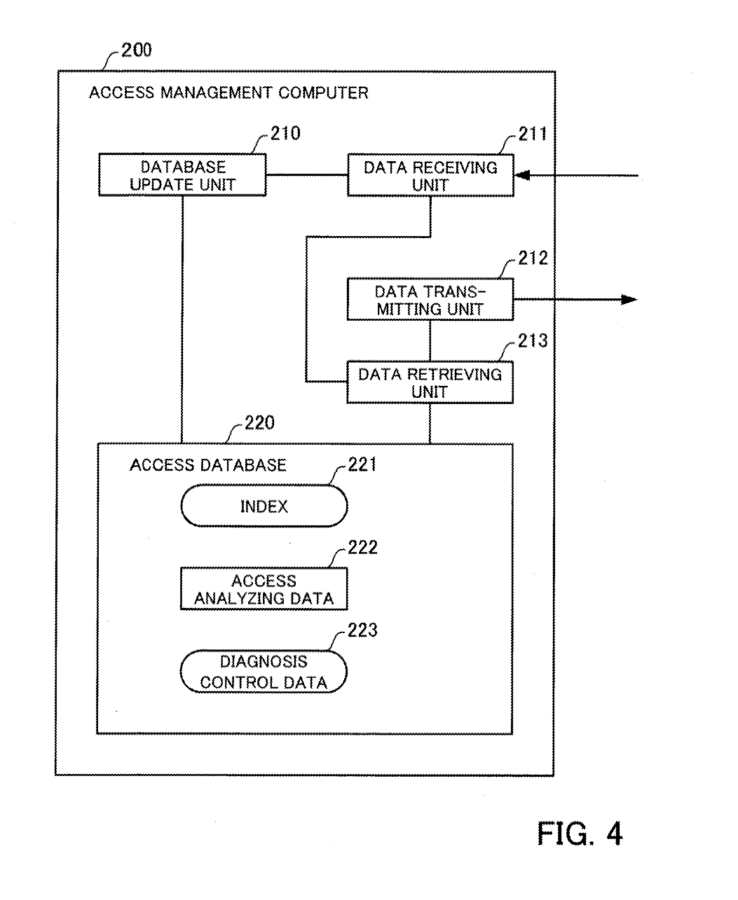

A configuration of the access management computer of the second embodiment will now be described below with reference to FIG. 4. FIG. 4 illustrates an exemplary configuration of the access management computer of the second embodiment.

The access management computer 200 manages the access database 220 and provides service functions using the access database 220 to each host computer 100. The access management computer 200 includes a database update unit 210, a data receiving unit 211, a data transmitting unit 212, a data retrieving unit 213, and an access database 220. The data receiving unit 211 receives data and requests from each host computer 100 via the network 19. In response to each received request, the data transmitting unit 212 transmits data to the requesting host computer 100 via the network 19.

The database update unit 210 updates the access database 220 with the data received by the data receiving unit 211 from each host computer 100. The data retrieving unit 213 acquires data from the access database 220 in response to a request received by the data receiving unit 211 from each host computer 100.

The access database 220 is a database that stores information such as access histories of HDDs 103 diagnosed by host computers 100. The access database 220 stores an index 221, access analyzing data 222, and diagnosis control data 223. The index 221 is used for identifying the access analyzing data 222 and diagnosis control data 223 corresponding to a particular combination of a host computer 100 and a HDD 103. The access analyzing data 222 is information relevant to access histories of HDDs 103. The diagnosis control data 223 is information relevant to the diagnosis control of HDDs 103. The host computer 100 executes a diagnosis of HDDs 103, using the access database 220 in the access management computer 200.

Note that the access history collecting unit 111, access history recording unit 112, and access analyzing unit 113 of each host computer 100, and the database update unit 210 of the access management computer 200 function in the same way as the generation unit 3 in the foregoing information processing apparatus of the first embodiment. Also, the diagnosis control unit 114 of the host computer 100 functions in the same way as the control unit 4 of the information processing apparatus of the first embodiment. Also, the diagnosis unit 115 of the host computer 100 functions in the same way as the diagnosis unit 5 of the information processing apparatus of the first embodiment.

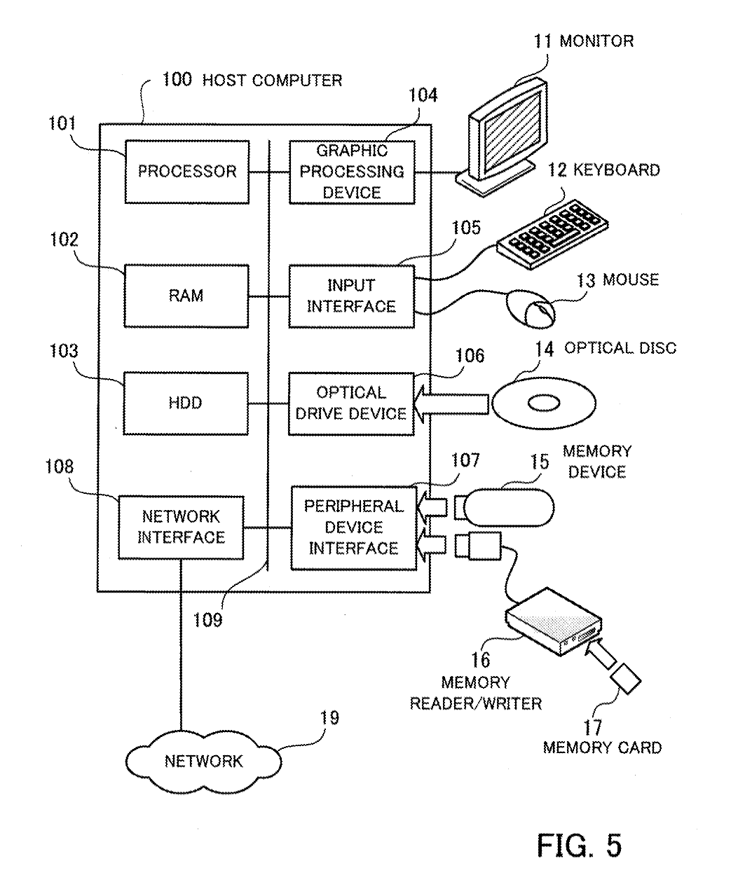

A hardware configuration of host computers 100 of the second embodiment will now be described below with reference to FIG. 5. FIG. 5 illustrates an exemplary hardware configuration of host computers of the second embodiment.

The illustrated host computer 100 is entirely controlled by a processor 101. The processor 101 is connected to a RAM (Random Access Memory) 102 and a plurality of peripheral devices via a bus 109. The processor 101 may be a multiprocessor. The processor 101 is, for example, CPU (Central Processing Unit), MPU (Micro Processing Unit), a DSP (Digital Signal Processor), ASIC (Application Specific Integrated Circuit), or PLD (Programmable Logic Device). Also, the processor 101 may be a combination of two or more processing components enumerated above.

The RAM 102 is used as the main storage device of the host computer 100. The RAM 102 temporarily stores at least a part of operating system (OS) programs and application programs executed by the processor 101. Also, the RAM 102 stores various types of data that is used by the processor 101.

Other devices connected to the bus 109 are an HDD 103, a graphic processing device 104, an input interface 105, an optical drive device 106, a peripheral device interface 107, and a network interface 108. The HDD 103 magnetically writes data on internal disks, and magnetically reads data from the same. The HDD 103 is used as an auxiliary storage device of the host computer 100. The HDD 103 stores OS programs, application programs, and various types of data. Semiconductor storage devices such as flash memory can also be used as the auxiliary storage device.

The graphic processing device 104 is connected to a monitor 11. The graphic processing device 104 displays an image on the screen of the monitor 11 in accordance with the command from the processor 101. The monitor 11 is a display device using a CRT (Cathode Ray Tube), a liquid crystal display device, or the like.

The input interface 105 is connected to a keyboard 12 and a mouse 13. The input interface 105 forwards signals transmitted from the keyboard 12 and the mouse 13 to the processor 101. Note that the mouse 13 is an example of a pointing device, and other pointing devices may be used. Other pointing devices are a touch panel, a tablet, a touch pad, a trackball, and so on.

The optical drive device 106 reads data recorded on an optical disc 14, utilizing laser light or the like. The optical disc 14 is a portable recording medium on which data is recorded in a readable manner by the reflection of the light. The optical disc 14 may be a DVD (Digital Versatile Disc), a DVD-RAM, a CD-ROM (Compact Disc Read Only Memory), a CD-R(Recordable)/RW (Rewritable) and so on.

The peripheral device interface 107 is the communication interface for connecting peripheral devices to the host computer 100. For example, the peripheral device interface 107 is used to connect a memory device 15 and a memory reader/writer 16. The memory device 15 is a recording medium equipped with a communication function with the peripheral device interface 107. The memory reader/writer 16 is a device that writes data in a memory card 17 or reads out data from the memory card 17. The memory card 17 is a recording medium having the shape of a card.

The network interface 108 is connected to the network 19. The network interface 108 transmits data to, and receives data from, other computers or communication devices via the network 19.

The processing functions of such host computers 100 of the second embodiment are realized by the above hardware platform of FIG. 5. The foregoing information processing apparatus 1 of the first embodiment and the access management computer 200 of the second embodiment can also be realized by using the same hardware configuration discussed above.

The host computer 100 realizes the processing functions of the second embodiment, for example, by executing a program recorded on a computer-readable recording medium. The program describing procedures executed by the host computer 100 may be recorded on various recording media, including the HDD 103, for example. The processor 101 loads at least a part of such programs stored in the HDD 103 into the RAM 102 before executing them. Also, the programs may be recorded on a portable recording medium, such as an optical disc 14, a memory device 15, and a memory card 17. The programs stored in the portable recording medium become executable after installed in the HDD 103 by the control from the processor 101, for example. Also, the processor 101 may read out the programs directly from the portable recording medium in order to execute them.

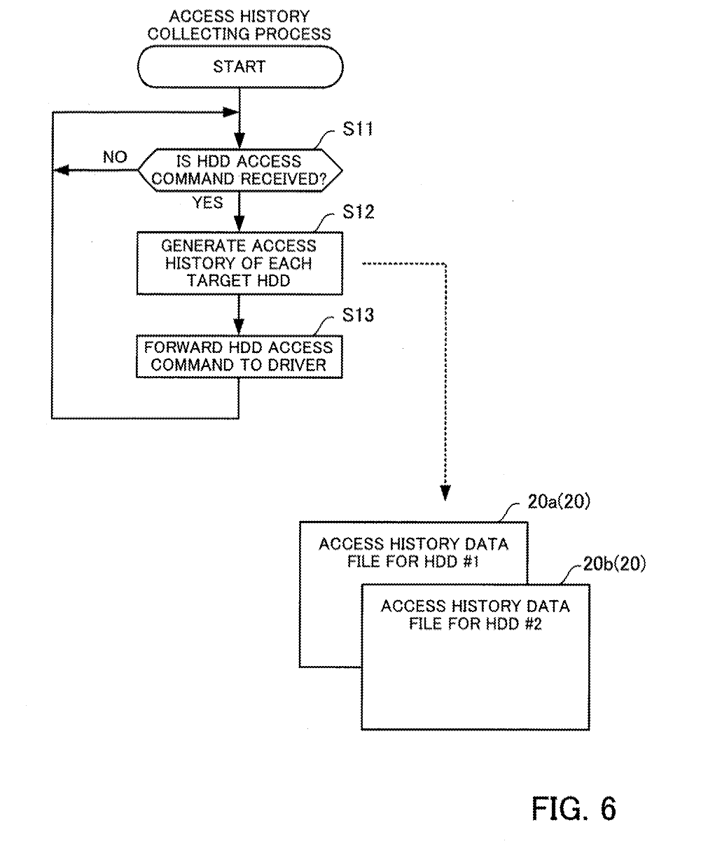

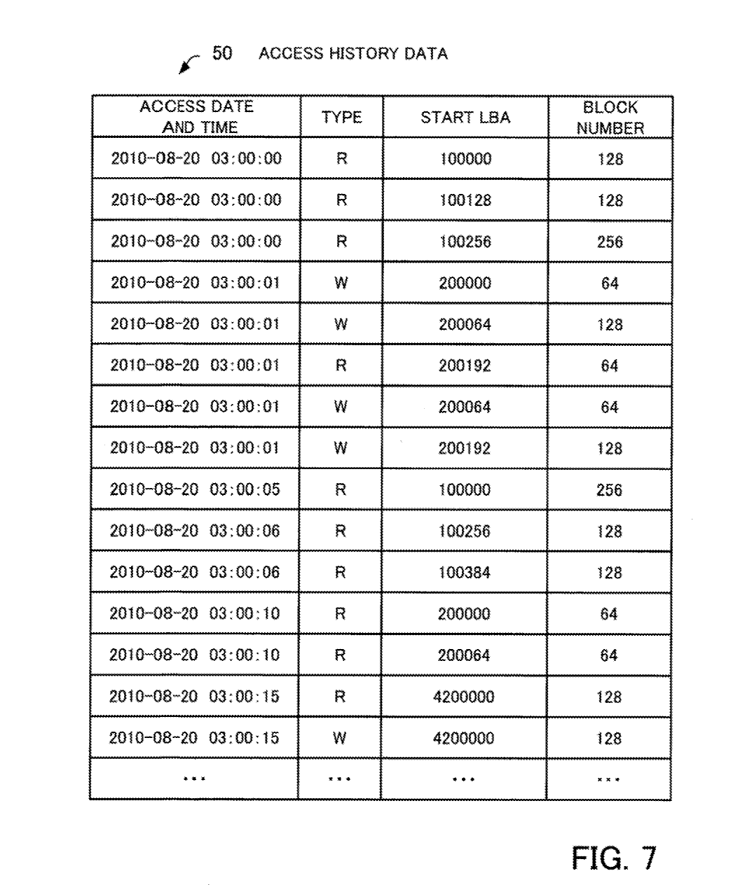

The following description will explain an access history collecting process executed by the access history collecting unit 111 in the host computer 100 of the second embodiment, with reference to FIGS. 6 and 7. FIG. 6 is a flowchart of an access history collecting process of the second embodiment.

The access history collecting process is a process to collect access history data. The access history collecting unit 111 starts this access history collecting process upon startup of the host computer 100 and keeps it running during the operation of the host computer 100.

[Step S11] The access history collecting unit 111 monitors communication between the application executing unit 110 and the driver 116, and determines whether an HDD access command (access request) is received. If the access history collecting unit 111 detects reception of an HDD access command, the access history collecting unit 111 proceeds to step S12. Otherwise, the access history collecting unit 111 awaits the arrival of HDD access commands.

[Step S12] The access history collecting unit 111 generates, in the access history recording unit 112, an access history data file 20 for each HDD 103 that the application executing unit 110 accesses (for example, one access history data file 20a for HDD #1, another access history data file 20b for HDD #2). The access history collecting unit 111 updates the access history data files 20, each time the access history collecting unit 111 receives an HDD access command.

[Step S13] The access history collecting unit 111 forwards the received HDD access command to the driver 116, and proceeds to step S11. During the process described above, the access history collecting unit 111 accumulates access history data by generating and updating the access history data file 20 of each HDD 103.

FIG. 7 illustrates an example of access history data of the second embodiment. The illustrated access history data 50 is an example of access history data accumulated in the access history data file 20. The access history data 50 is a collection of records representing access date and time, type, start LBA, and block number. The access date and time field of a record indicates when the HDD 103 was accessed by the application executing unit 110. The access date and time field represents a date and time in the order of seconds. The type (access type) field contains information indicating whether the access to the HDD 103 was to read data (R) or to write data (W). The start LBA field contains information identifying the position on the HDD 103 at which the access started. The block number field contains information identifying the amount of accessed data, which is represented by, for example, the number of accessed LBA blocks.

The access history collecting unit 111 thus records data about activities of a specific HDD 103, which includes the reception date and time of each HDD access command, type of the received HDD access command, access position, and amount of data. These records are accumulated in an access history data file 20. For example, the access history data 50 records the fact that a HDD access command for a specific HDD 103 was received at “2010-08-20 03:00:00” (exactly at 3 a.m. on Aug. 20, 2010). More particularly, this HDD access command caused a read operation (type “R”) on the 128 blocks (block number “128”) starting at LBA address 10000 (start LBA “100000”). Note that the access history data 50 may be simplified to include only the access date and time and the block number. Also, the access history data 50 may be expanded to include more information items than those discussed above.

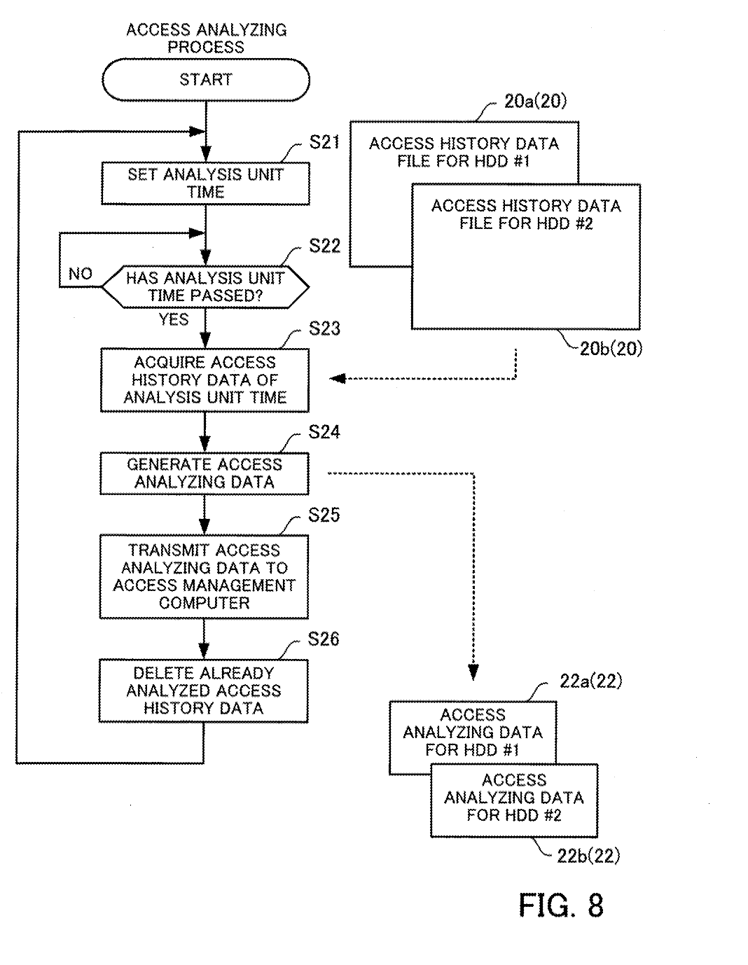

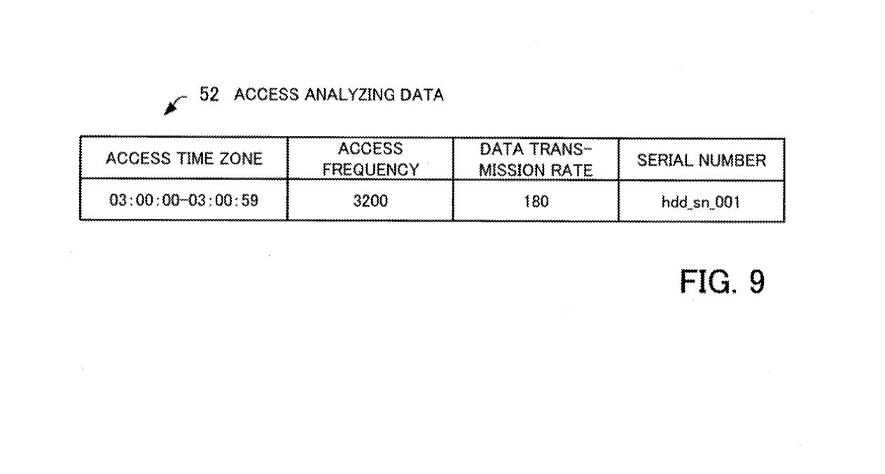

The following description will explain an access analyzing process executed by the access analyzing unit 113 of the host computer 100 of the second embodiment, with reference to FIGS. 8 and 9. FIG. 8 is a flowchart of an access analyzing process of the second embodiment. This access analyzing process is to analyze the collected access history data. The access analyzing unit 113 starts the access analyzing process upon startup of the host computer 100 and keeps it running during the operation of the host computer 100.

[Step S21] The access analyzing unit 113 sets an analysis unit time. The analysis unit time is a unit time duration for the access analyzing unit 113 to analyze access history data. For example, the analysis unit time is set to one minute.

[Step S22] The access analyzing unit 113 awaits the passage of the analysis unit time. If the analysis unit time has passed, the access analyzing unit 113 proceeds to step S23.

[Step S23] The access analyzing unit 113 acquires the access history data of an analysis unit time, from the access history data file 20 of each HDD 103.

[Step S24] The access analyzing unit 113 analyzes the access history data to generate access analyzing data 22 for each HDD (for example, access analyzing data 22a for HDD #1, access analyzing data 22b for HDD #2).

[Step S25] The access analyzing unit 113 transmits the access analyzing data 22 to the access management computer 200 via the network 19.

[Step S26] The access analyzing unit 113 deletes the analyzed records of access history data from the access history data files 20, and returns to step S21.

In this way, the access analyzing unit 113 generates access analyzing data 22 of an analysis unit time for each HDD 103.

FIG. 9 illustrates an example of access analyzing data of the second embodiment. The access analyzing data 52 is an exemplary result of access history data analysis. The illustrated access analyzing data 52 includes an access time zone, an access frequency, a data transmission rate, and a serial number. The access time zone indicates a specific period that the access analyzing unit 113 has analyzed. The serial number is a recording device identifier that uniquely identifies the HDD 103 of interest. For example, a unique serial number is attached to each HDD 103.

The access frequency and the data transmission rate are calculated by the access analyzing unit 113 from the access history data. The access frequency represents how many times the HDD 103 was accessed during the access time zone of interest. For example, the access frequency is the number of access operations per unit time (analysis unit time). The data transmission rate represents at what rate the data was transmitted to and from the HDD 103 during the access time zone of interest. For example, the data transmission rate is the amount of transmitted data per unit time (analysis unit time).

In the above process, the access analyzing unit 113 selects an access time zone for each HDD 103 to calculate access frequencies and data transmission rates. For example, the access analyzing unit 113 generates access analyzing data 52 for the HDD 103 with a serial number “hdd_sn_{—}001”. In the access analyzing data 52, the access frequency and data transmission rate in an access time zone “03:00:00 to 03:00:59” (i.e., 60-second analysis unit time period from 3 a.m.) are generated. More specifically, the access frequency is 3200 times/minute, and the data transmission rate is 180 MB/minute.

Note that the access analyzing unit 113 may output other indexes that make it possible to evaluate the load on HDDs 103, such as a load factor for the performance of each HDD 103, instead of the combination of access frequency and transmission rate. Also, the access time zone is not limited to the form of “hour:minute:second”, but may further include calendar date information as in “year, month, day”. Also, the access time zone is not limited to the above-described date and time format, but may be expressed by an incremental time code that starts upon startup of the host computer 100.

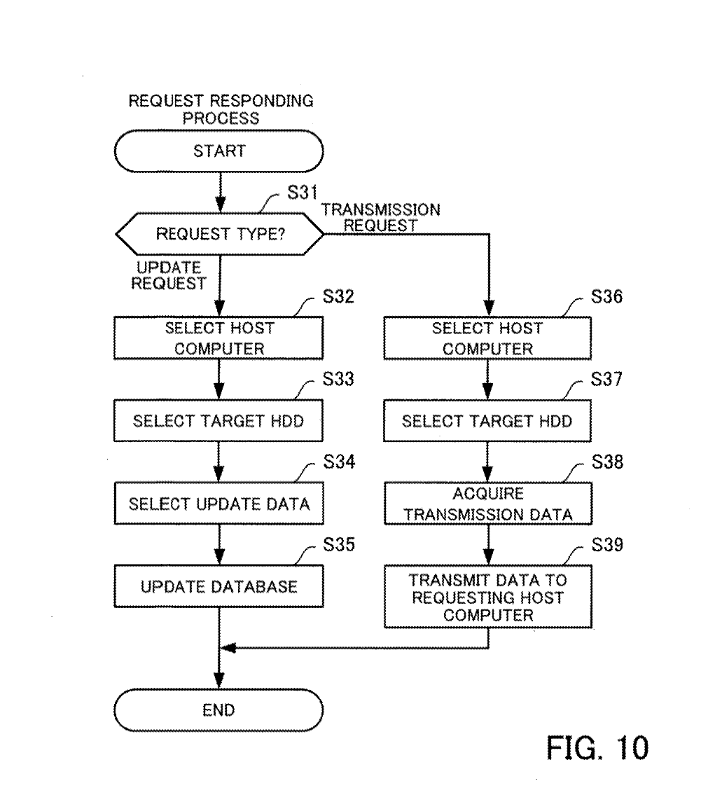

The following description will explain a request responding process executed by the access management computer 200 of the second embodiment, with reference to FIGS. 10 to 13. FIG. 10 is a flowchart of a request responding process of the second embodiment.

The request responding process is a process of the access management computer 200 in response to a request from a host computer 100 to the access database 220. The data receiving unit 211 receives the request from a host computer 100 to the access database 220, in order for the access management computer 200 to execute the request responding process.

The request to the access database 220 from a host computer 100 includes a request for updating the access database 220, and a request for transmitting data included in the access database 220. The update request requests that the access analyzing data 222 included in the access database 220 be updated to include the access analyzing data 222 obtained from the host computer 100. The transmission request requests the access analyzing data 222 and the diagnosis control data 223 of the HDD 103 that is to be diagnosed by the host computer 100.

[Step S31] The data receiving unit 211 determines the type of the request transmitted from the host computer 100 to the access database 220. If the type of the request is update request, the data receiving unit 211 proceeds to step S32. If the type of the request is transmission request, the data receiving unit 211 proceeds to step S36.

[Step S32] The database update unit 210 selects the host computer 100 that has transmitted the update request to the access database 220. The database update unit 210 selects the host computer 100 on the basis of the header of communicated data, for example.

[Step S33] The database update unit 210 selects a HDD 103 on the basis of the access analyzing data 222 that is combined with the update request when received from the host computer 100.

[Step S34] The database update unit 210 searches the index 221 using information indicating the host computer 100 and the HDD 103 as a key, to select data (update data) that is to be updated in the access database 220.

[Step S35] The database update unit 210 updates the access database 220 on the basis of the selected host computer 100, the selected HDD 103, and the selected update data, and ends the request responding process. The access database 220 has a predetermined storage capacity for each HDD 103. The database update unit 210 updates the access database 220 by overwriting old data. The predetermined storage capacity for each HDD 103 is, for example, of the size that can store access analyzing data 222 of last twenty-four hours.

[Step S36] The data retrieving unit 213 selects the host computer 100 that has requested a transmission to the access database 220. The data retrieving unit 213 selects the host computer 100 on the basis of the header of communicated data, for example.

[Step S37] The data retrieving unit 213 selects a HDD 103 on the basis of the transmission request from the host computer 100. The transmission request from the host computer 100 includes information identifying the HDD 103 that is to be diagnosed by the host computer 100.

[Step S38] The data retrieving unit 213 searches the index 221 using information indicating the host computer 100 and the HDD 103 as a key, to select data that is to be transmitted, and acquires data transmitted from the access database 220. The transmitted data includes access analyzing data 222 and diagnosis control data 223.

The transmission request from the host computer 100 includes information identifying access analyzing data 222 and diagnosis control data 223 of the HDD 103 that is to be diagnosed by the host computer 100. For example, the transmission request from the host computer 100 includes information specifying an access time zone. Note that, when an access time zone is uniquely identified from a time point at which the transmission request is received from the host computer 100, the transmission request from the host computer 100 is sufficient even without information specifying an access time zone. For example, the data retrieving unit 213 may select a time zone twenty-four hours (which is preset) earlier than the time point at which the transmission request is received from the host computer 100, as an access time zone.

[Step S39] The data transmitting unit 212 transmits access analyzing data 222 and diagnosis control data 223 (transmission data) acquired by the data retrieving unit 213, to the host computer 100 that has requested the transmission, and ends the request responding process.

In this way, the access management computer 200 accumulates a predetermined amount of access analyzing data 222 (including access analyzing data segments of each analysis unit time for a predetermined period) in the access database 220 for each HDD 103.

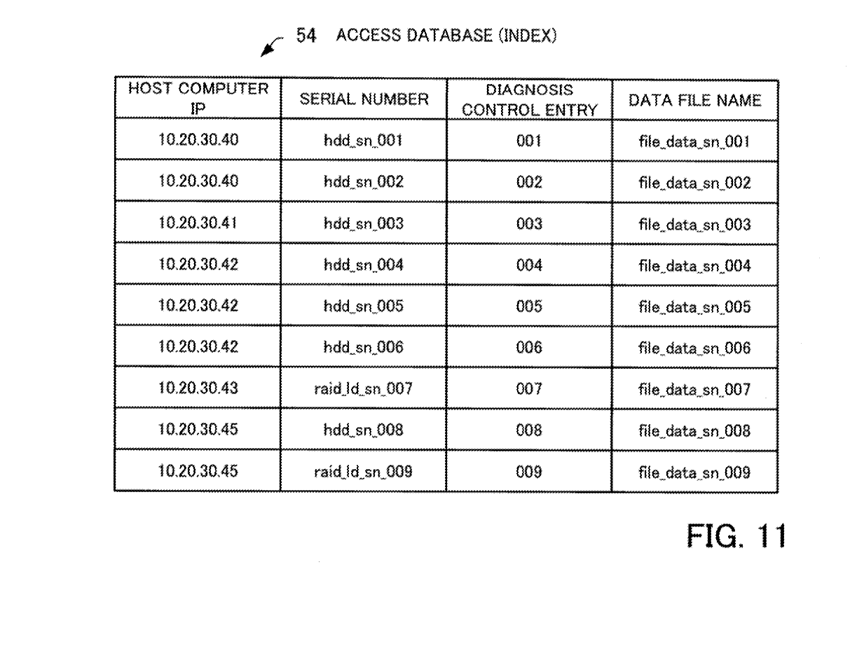

FIG. 11 illustrates an example of the access database (index) of the second embodiment. As illustrated in FIG. 4, the access database 220 has a data structure including an index 221, access analyzing data 222, and diagnosis control data 223. The access database (index) 54 illustrated in FIG. 11 is an example of the index 221. The access database (index) 54 is index data of the access database 220.

The access database (index) 54 includes host computer IP, serial number, diagnosis control entry, and data file name. The host computer IP is an IP address used in the network 19. The host computer IP serves as terminal device identifying information for uniquely identifying a computer connected to the network 19.

The serial number is a serial number attached to each HDD 103. The serial number serves as a recording device identifier for uniquely identifying a HDD 103. The serial number is collected from access analyzing data 52 sent from the host computer 100.

The diagnosis control entry is an entry given to each data piece included in the diagnosis control data 223, and serves as diagnosis control data identifying information for uniquely identifying a data piece. The data file name is a file name given to each data file included in the access analyzing data 222, and serves as access analyzing data identifying information for uniquely identifying a data file.

The access management computer 200 manages the access to the analyzing data 222 and the diagnosis control data 223, using the index 221. For example, according to the access database (index) 54, the host computer 100 selected by a host computer IP “10.20.30.40” diagnoses the HDD 103 selected by a serial number “hdd_sn_{—}001”. Note that the HDD 103 selected by a serial number is not limited to one HDD, but may be a storage system configured by a plurality of HDDs. The HDD 103 selected by the serial number “hdd_sn_{—}001” has the diagnosis control data 223 of diagnosis control entry “001”, and the access analyzing data 222 of data file name “file_data_sn_{—}001”.

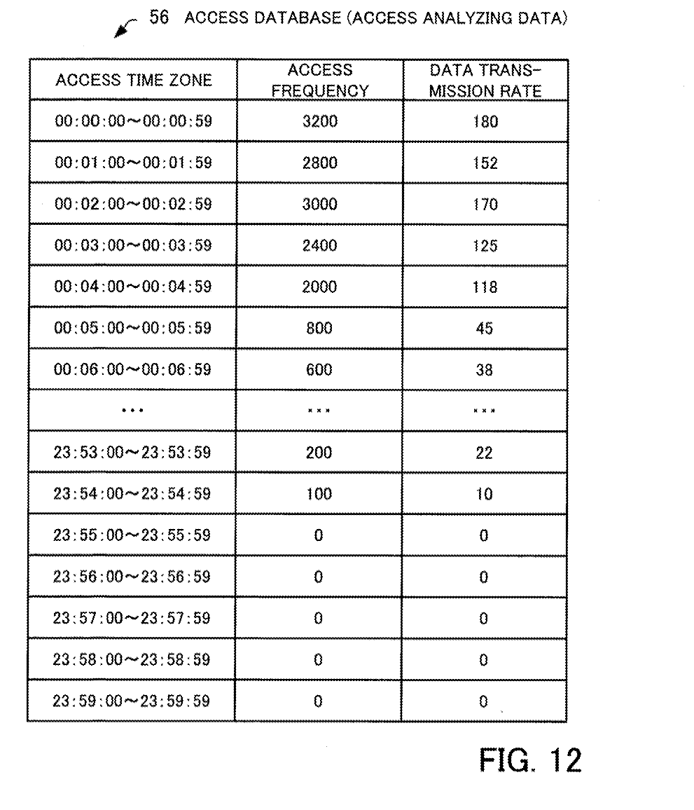

FIG. 12 illustrates an example of the access database (access analyzing data) of the second embodiment. The access analyzing data 222 identified by the index 221 is structured, for example, as in the access database (access analyzing data) 56 illustrated in FIG. 12. The access database (access analyzing data) 56 accumulates a twenty-four-hour (accumulation period) amount of access frequencies and data transmission rates, the access frequencies and the data transmission rates consisting of values for each one minute (analysis unit time). For example, the access frequency and the data transmission rate in an access time zone “00:00:00 to 00:00:59 (i.e., 60 seconds from 0 a.m.)” are “3200 (3200 times/minute)” and “180 (MB/minute)”, respectively.

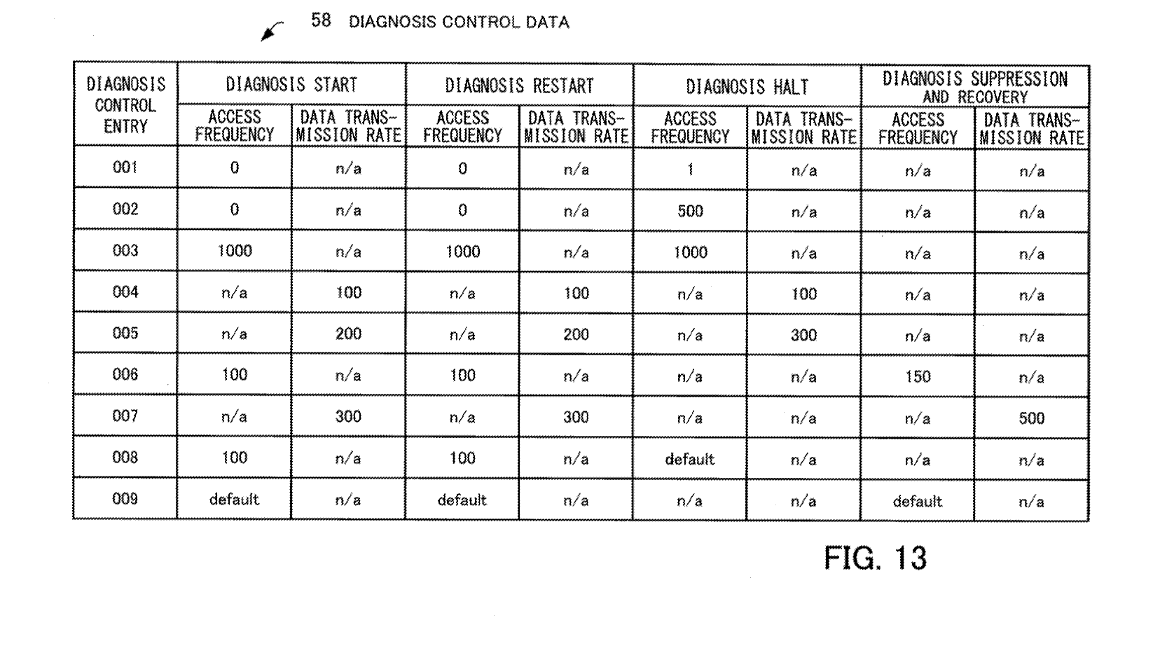

FIG. 13 illustrates an example of the diagnosis control data of the second embodiment. The diagnosis control data 223 identified by the index 221 is structured, for example, as in the diagnosis control data 58 illustrated in FIG. 13. The diagnosis control data 58 contains diagnosis control entries of each HDD 103. The diagnosis control data 58 contains access frequency threshold values and transmission rate threshold values for determining “diagnosis start”, “diagnosis restart”, “diagnosis halt”, “diagnosis suppression and recovery”, with respect to each diagnosis control entry. For example, in the HDD 103 corresponding to the diagnosis control entry “001”, diagnosis is started or restarted at access frequency “0 (times/minute)”, and the diagnosis halts at access frequency “1 (times/minute)”. Note that “n/a (not available)” means a state that is undefined or not set. Also, “default” means an initial set value, and for example a fifty percent value of the maximum access frequency or transmission rate. Note that, the diagnosis control data 223 may be maintained and managed by an administrator who manages the access management computer 200. Alternatively, the diagnosis control data 223 may be updated and managed by a user of a host computer 100. Also, a host computer 100 or the access management computer 200 may set the access frequency threshold values and the transmission rate threshold values in accordance with an application for accessing a HDD 103. In this way, the access management computer 200 keeps the access database 220 up to date in response to an update request from a host computer 100, and replies to a transmission request from a host computer 100.

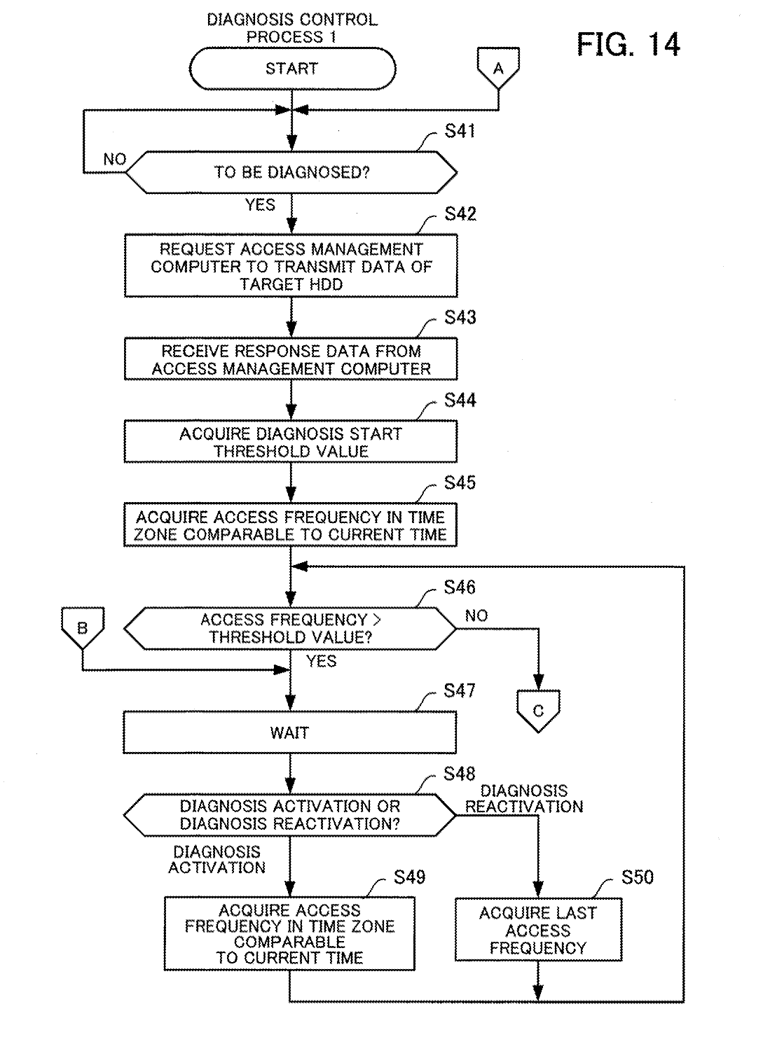

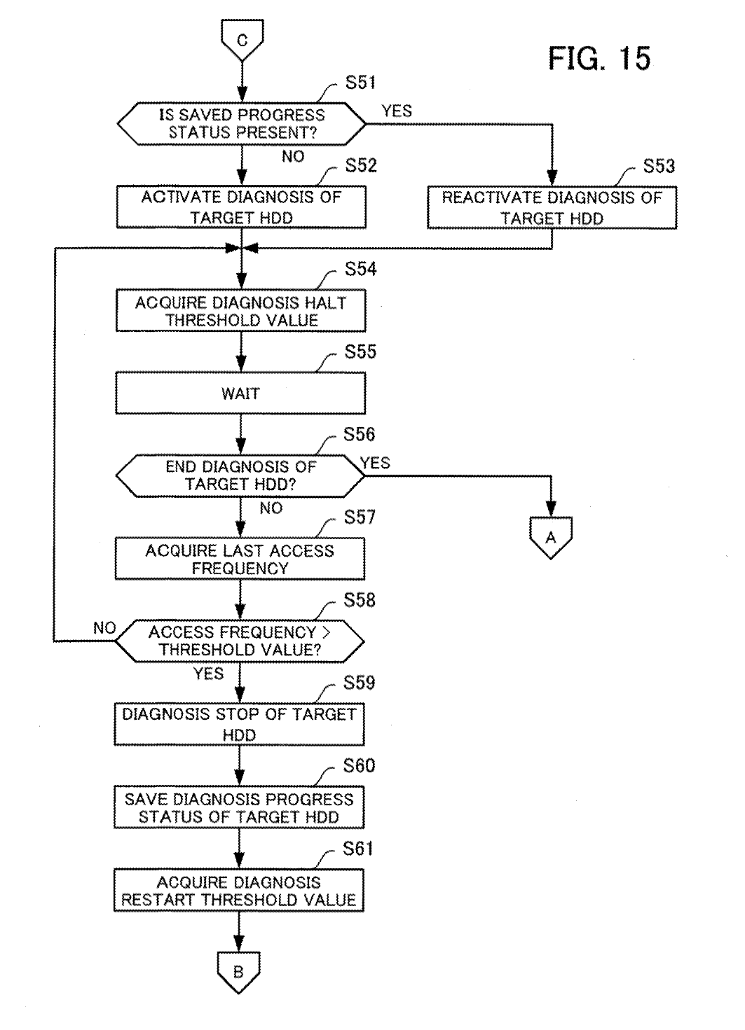

Next, the following description will explain a diagnosis control process (1) executed by the diagnosis control unit 114 of each host computer 100 of the second embodiment, with reference to FIGS. 14 and 15. FIGS. 14 and 15 are a flowchart of the diagnosis control process (1) of the second embodiment.

The diagnosis control executed by the diagnosis control unit 114 includes a diagnosis control process (1) that controls a diagnosis on the basis of access frequency of a HDD 103, and a diagnosis control process (2) that controls a diagnosis on the basis of data transmission rate of a HDD 103. The diagnosis control unit 114 determines whether the diagnosis control is executed by the diagnosis control process (1) or the diagnosis control process (2), on the basis of diagnosis control data 223, for each HDD 103.

The diagnosis control process (1) is chosen when a diagnosis of a HDD 103 by the diagnosis unit 115 is controlled on the basis of access frequencies. More specifically, the diagnosis control process (1) controls the diagnosis unit 115, so as not to interrupt the application executing unit 110 during its access to the HDD 103. The diagnosis control process (1) is invoked upon startup of the host computer 100, and is executed during the operation of the host computer 100.

[Step S41] The diagnosis control unit 114 determines whether or not a diagnosis is to be executed for a target HDD 103. For example, the diagnosis control unit 114 checks a preset diagnosis schedule, a request received from a user, and other diagnosis conditions, and determines whether or not a diagnosis of the HDD 103 is to be executed. If the diagnosis control unit 114 determines that a diagnosis is to be executed, the diagnosis control unit 114 proceeds to step S42. If the diagnosis control unit 114 determines that a diagnosis is not to be executed, the diagnosis control unit 114 waits until the condition for starting a diagnosis is established.

[Step S42] The diagnosis control unit 114 requests access analyzing data 222 and diagnosis control data 223 relevant to the target HDD 103, to the access management computer 200.

[Step S43] The diagnosis control unit 114 receives the access analyzing data 222 and the diagnosis control data 223 relevant to the target HDD 103, from the access management computer 200.

[Step S44] The diagnosis control unit 114 acquires an access frequency threshold value of diagnosis start, from the diagnosis control data 223.

[Step S45] The diagnosis control unit 114 acquires the current time, and acquires an access frequency in the access time zone that is comparable to the current time, from the access analyzing data 222. For example, when access history of the HDD 103 indicates a twenty-four hour cycle, the diagnosis control unit 114 acquires the access frequency of twenty-four hours earlier than the current time, for comparison at the next step.

[Step S46] The diagnosis control unit 114 compares the access frequency acquired from the access analyzing data 222 with a threshold value noted below. If the access frequency is higher than the threshold value, the diagnosis control unit 114 proceeds to step S47. If the access frequency is equal to or lower than the threshold value, the diagnosis control unit 114 proceeds to step S51.

Note that, with respect to the threshold value that is compared with the access frequency in step S46, the threshold value of diagnosis start acquired in step S44 is set initially (step S44), and the threshold value of diagnosis restart is set after a halt of diagnosis (step S61 described later).

[Step S47] The diagnosis control unit 114 stands by for a wait time (for example, for one-minute analysis unit time), because the diagnosis control unit 114 has determined that the access to a HDD 103 from the application executing unit 110 is interrupted within the current time period. After the wait time is over, the diagnosis control unit 114 proceeds to step S48. Note that the wait time may be set at an arbitrary time for each HDD 103. Also, the wait time for diagnosis start and the wait time for diagnosis restart may be set at different times from each other.

[Step S48] The diagnosis control unit 114 determines whether the diagnosis of the target HDD 103 is a newly started diagnosis (diagnosis activation), or a diagnosis that restarts a halted diagnosis (diagnosis reactivation). This determination is performed by determining whether or not there is a saved progress status. If the diagnosis control unit 114 determines the diagnosis activation, the diagnosis control unit 114 proceeds to step S49. If the diagnosis control unit 114 determines the diagnosis reactivation, the diagnosis control unit 114 proceeds to step S50.

[Step S49] The diagnosis control unit 114 acquires the current time, and acquires the access frequency in the access time zone that is comparable to the current time, from the access analyzing data 222.

[Step S50] The diagnosis control unit 114 acquires the access frequency of the last access time zone (i.e., the latest access frequency analyzed by the access analyzing unit 113) from the access analyzing unit 113.

[Step S51] The diagnosis control unit 114 determines whether or not there is a progress status saved for a diagnosis of the target HDD 103. The saved progress status is information of a progress up to a halt, and enables a restart of a diagnosis of a HDD 103 which has halted before completing. If there is a progress status, that is, if a halted diagnosis is to be restarted, the diagnosis control unit 114 proceeds to step S53. On the other hand, if there is no progress status, that is, if a new diagnosis is to be started, the diagnosis control unit 114 proceeds to step S52.

[Step S52] The diagnosis control unit 114 instructs a diagnosis activation (diagnosis start) to the diagnosis unit 115.

[Step S53] The diagnosis control unit 114 instructs a diagnosis reactivation (diagnosis restart) based on the saved progress status, to the diagnosis unit 115.

[Step S54] The diagnosis control unit 114 acquires an access frequency threshold value of diagnosis halt, from the diagnosis control data 223.

[Step S55] The diagnosis control unit 114 stands by for a wait time (for example, for one-minute analysis unit time) until a diagnosis end or a diagnosis halt is determined. Note that the wait time may be set at an arbitrary time for each HDD 103.

[Step S56] The diagnosis control unit 114 determines whether or not the diagnosis of a HDD 103 of the diagnosis target has ended. The diagnosis control unit 114 sends an inquiry to the diagnosis unit 115 about the progress of the diagnosis of the HDD 103 in order to determine the diagnosis end of the HDD 103. If the diagnosis has ended, the diagnosis control unit 114 proceeds to step S41, and awaits the next diagnosis start time. On the other hand, if the diagnosis has not ended, the diagnosis control unit 114 proceeds to step S57.

[Step S57] The diagnosis control unit 114 acquires the current time, and acquires the access frequency of the last access time zone from the access analyzing unit 113.

[Step S58] The diagnosis control unit 114 compares the access frequency acquired from the access analyzing unit 113, with the threshold value of diagnosis halt acquired in step S54. If the access frequency is higher than the threshold value, the diagnosis control unit 114 proceeds to step S59. If the access frequency is equal to or lower than the threshold value, the diagnosis control unit 114 proceeds to step S54. That is, if the access frequency is higher than the threshold value, the diagnosis control unit 114 halts the diagnosis. If the access frequency is equal to or lower than the threshold value, the diagnosis control unit 114 continues the diagnosis.

[Step S59] The diagnosis control unit 114 instructs a diagnosis stop (diagnosis halt) to the diagnosis unit 115.

[Step S60] The diagnosis control unit 114 saves the progress status of the diagnosis of the target HDD 103, in a predetermined storage unit (for example, the RAM 102).

[Step S61] The diagnosis control unit 114 acquires an access frequency threshold value of diagnosis restart, from the diagnosis control data 223. The diagnosis control unit 114 proceeds to step S47, and awaits a diagnosis restart time.

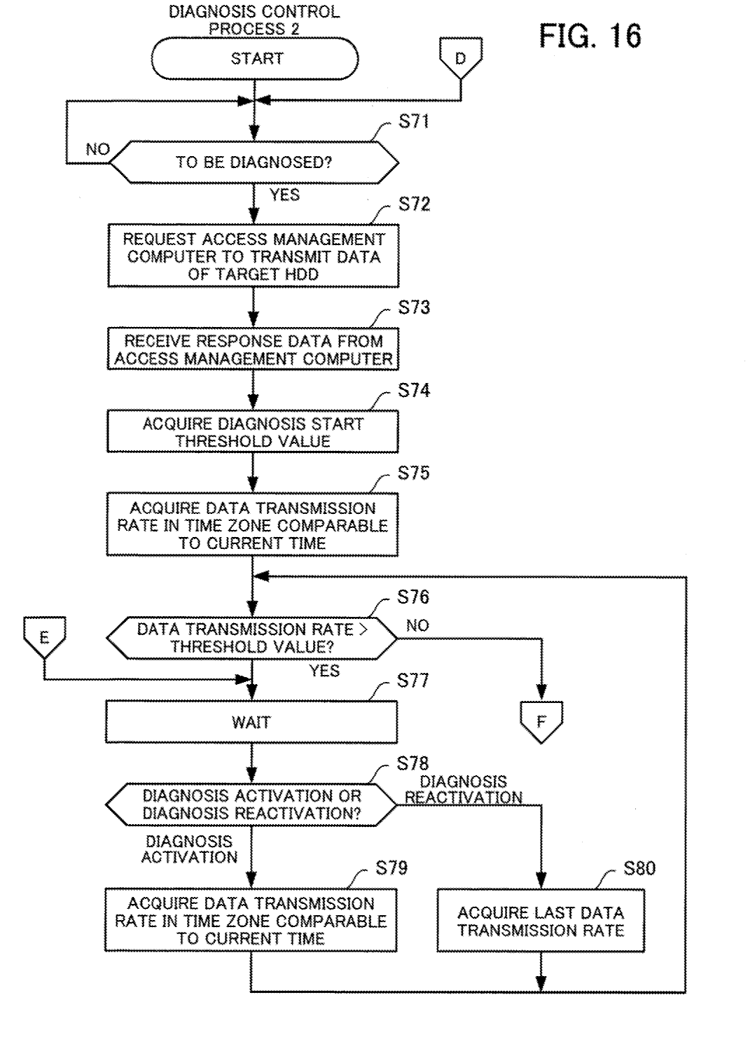

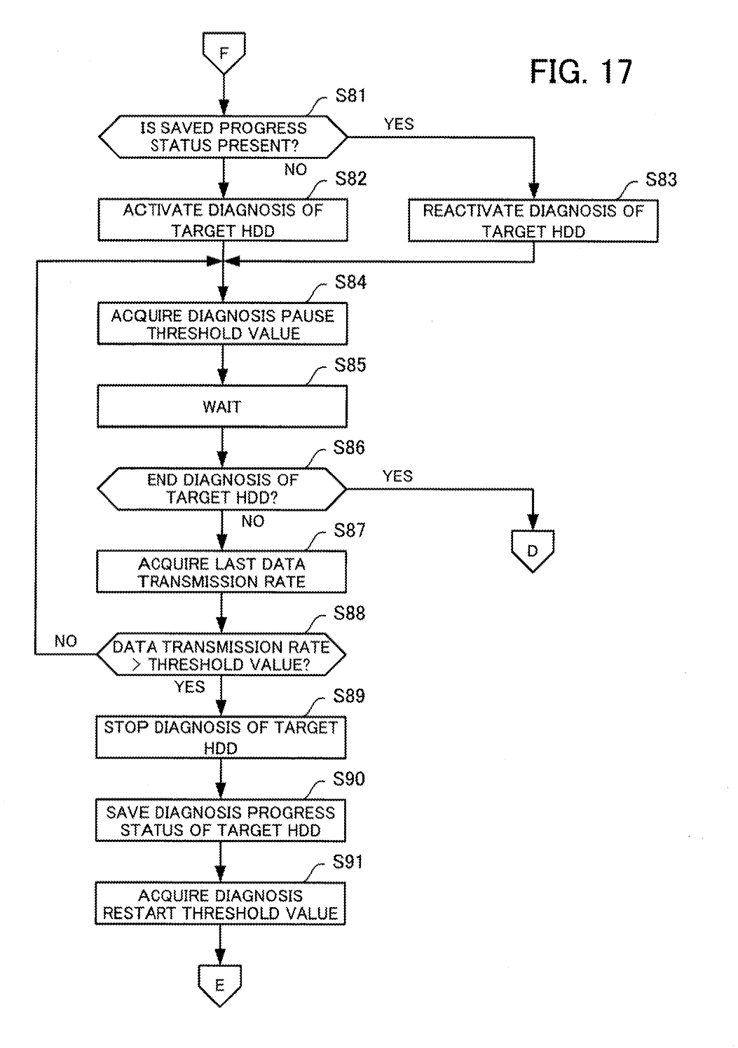

Next, the following description will explain the diagnosis control process (2) executed by the diagnosis control unit 114 of each host computer 100 of the second embodiment, with reference to FIGS. 16 and 17. FIGS. 16 and 17 is a flowchart of the diagnosis control process (2) of the second embodiment.

The diagnosis control process (2) is chosen when a diagnosis of a HDD 103 by the diagnosis unit 115 is controlled on the basis of data transmission rates. More specifically, the diagnosis control process (2) controls the diagnosis unit 115, so as not to interrupt the application executing unit 110 during its access to the HDD 103. The diagnosis control process (2) is invoked upon startup of the host computer 100, and is executed during the operation of the host computer 100.

[Step S71] The diagnosis control unit 114 determines whether or not a diagnosis is to be executed for a target HDD 103. For example, the diagnosis control unit 114 checks a preset diagnosis schedule, a request received from a user, and other diagnosis conditions, and determines whether or not a diagnosis of a HDD 103 is to be executed. If the diagnosis control unit 114 determines that a diagnosis is to be executed, the diagnosis control unit 114 proceeds to step S72. If the diagnosis control unit 114 determines that a diagnosis is not to be executed, the diagnosis control unit 114 waits until the condition for starting a diagnosis is established.

[Step S72] The diagnosis control unit 114 requests access analyzing data 222 and diagnosis control data 223 relevant to the target HDD 103, to the access management computer 200.

[Step S73] The diagnosis control unit 114 receives the access analyzing data 222 and the diagnosis control data 223 relevant to the target HDD 103, from the access management computer 200.

[Step S74] The diagnosis control unit 114 acquires a data transmission rate threshold value of diagnosis start, from the diagnosis control data 223.

[Step S75] The diagnosis control unit 114 acquires the current time, and acquires the data transmission rate in the access time zone that is comparable to the current time, from the access analyzing data 222. For example, when the access history of the HDD 103 indicates a twenty-four hour cycle, the diagnosis control unit 114 acquires the data transmission rate of twenty-four hours earlier than the current time as a target for comparison.

[Step S76] The diagnosis control unit 114 compares the data transmission rate acquired from the access analyzing data 222, with the threshold value. If the data transmission rate is higher than the threshold value, the diagnosis control unit 114 proceeds to step S77. If the data transmission rate is equal to or lower than the threshold value, the diagnosis control unit 114 proceeds to step S81.

Note that, with respect to the threshold value that is compared with the data transmission rate in step S76, the threshold value of diagnosis start acquired in step S74 is set initially (step S74), and the threshold value of diagnosis restart is set after a halt of diagnosis (step S91 described later).

[Step S77] The diagnosis control unit 114 stands by for a wait time (for example, for one-minute analysis unit time), because the diagnosis control unit 114 has determined that the access to a HDD 103 from the application executing unit 110 is interrupted within the current time period. After the wait time is over, the diagnosis control unit 114 proceeds to step S78. Note that the wait time may be set at an arbitrary time for each HDD 103. Also, the wait time for diagnosis start and the wait time for diagnosis restart may be set at different times from each other.

[Step S78] The diagnosis control unit 114 determines whether the diagnosis of the target HDD 103 is a newly started diagnosis (diagnosis activation), or a diagnosis that restarts a halted diagnosis (diagnosis reactivation). This determination is performed by determining whether or not there is a saved progress status. If the diagnosis control unit 114 determines the diagnosis activation, the diagnosis control unit 114 proceeds to step S79. If the diagnosis control unit 114 determines the diagnosis reactivation, the diagnosis control unit 114 proceeds to step S80.

[Step S79] The diagnosis control unit 114 acquires the current time, and acquires the data transmission rate in the access time zone that is comparable to the current time, from the access analyzing data 222.

[Step S80] The diagnosis control unit 114 acquires the data transmission rate of the last access time zone (i.e., the latest data transmission rate analyzed by the access analyzing unit 113) from the access analyzing unit 113.

[Step S81] The diagnosis control unit 114 determines whether or not there is a progress status saved for diagnosis of the target HDD 103. The saved progress status is information of a progress up to a halt, which enables a restart of a diagnosis of a HDD 103 which has halted before completing. If there is a progress status, that is, if a halted diagnosis is to be restarted, the diagnosis control unit 114 proceeds to step S83. On the other hand, if there is no progress status, that is, if a new diagnosis is to be started, the diagnosis control unit 114 proceeds to step S82.

[Step S82] The diagnosis control unit 114 instructs a diagnosis activation (diagnosis start) to the diagnosis unit 115.

[Step S83] The diagnosis control unit 114 instructs a diagnosis reactivation (diagnosis restart) based on the saved progress status, to the diagnosis unit 115.

[Step S84] The diagnosis control unit 114 acquires a data transmission rate threshold value of diagnosis halt, from the diagnosis control data 223.

[Step S85] The diagnosis control unit 114 stands by for a wait time (for example, for one-minute analysis unit time) until a diagnosis end or a diagnosis halt is determined. Note that the wait time may be set at an arbitrary time for each HDD 103.

[Step S86] The diagnosis control unit 114 determines whether or not the diagnosis of the target HDD 103 has ended. The diagnosis control unit 114 sends an inquiry to the diagnosis unit 115 about the progress of the diagnosis of the HDD 103 in order to determine the diagnosis end of the HDD 103. If the diagnosis has ended, the diagnosis control unit 114 proceeds to step S71, and awaits the next diagnosis start time. On the other hand, if the diagnosis has not ended, the diagnosis control unit 114 proceeds to step S87.

[Step S87] The diagnosis control unit 114 acquires the current time, and acquires the data transmission rate of the last access time zone from the access analyzing unit 113.

[Step S88] The diagnosis control unit 114 compares the data transmission rate acquired from the access analyzing unit 113, with the threshold value of diagnosis halt acquired in step S84. If the data transmission rate is higher than the threshold value, the diagnosis control unit 114 proceeds to step S89. If the data transmission rate is equal to or lower than the threshold value, the diagnosis control unit 114 proceeds to step S84. That is, if the data transmission rate is higher than the threshold value, the diagnosis control unit 114 halts the diagnosis. If the data transmission rate is equal to or lower than the threshold value, the diagnosis control unit 114 continues the diagnosis.

[Step S89] The diagnosis control unit 114 instructs a diagnosis stop (diagnosis halt) to the diagnosis unit 115.

[Step S90] The diagnosis control unit 114 saves the progress status of the diagnosis of the target HDD 103, in a predetermined storage unit (for example, the RAM 102).

[Step S91] The diagnosis control unit 114 acquires a data transmission rate threshold value of diagnosis restart, from the diagnosis control data 223. The diagnosis control unit 114 proceeds to step S77, and awaits the diagnosis restart time.

In this way, the diagnosis control unit 114 controls the start, halt, and restart of a diagnosis of a target HDD 103 under test. Also, the host computer 100 determines when to start a diagnosis of the HDD 103 from its access history in the past, and thus eliminates the need for the time of monitoring access status of the HDD 103 before starting its diagnosis. Accordingly, the host computer 100 selects an appropriate time for starting a diagnosis of the HDD 103, without time lags. Further, the host computer 100 determines whether and when to halt or restart an ongoing diagnosis on the basis of the current access status (access frequency or the data transmission rate). The host computer 100 keeps the HDD 103 from an excessive access load, even when the application executing unit 110 accesses the HDD 103 without periodicity (for example, access triggered by events such as activation of an application). Because the host computer 100 is able to choose a better time to start a diagnosis with a moderate access load on the HDD 103, the diagnosis is less likely to halt in the middle of execution. The host computer 100 thus efficiently diagnoses its HDD 103.

The above-described diagnosis control process (1) and diagnosis control process (2) decide starting a diagnosis on the basis of history records, as well as halting and restarting on the basis of the current situation. Alternatively, it may also be possible to halt an ongoing diagnosis on the basis of the current situation, while restarting it on the basis of history records. In this way, the host computer 100 allows a diagnosis to halt without allowing the application executing unit 110 to overload the HDD 103, so that the diagnosis restarts with no time lags.

### Third Embodiment

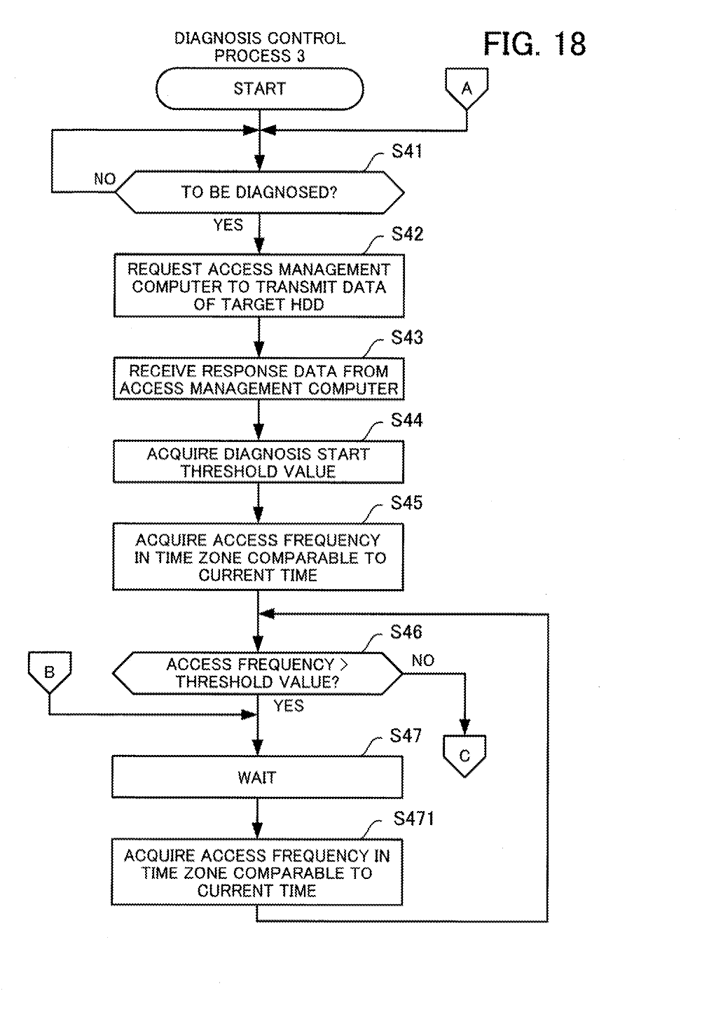

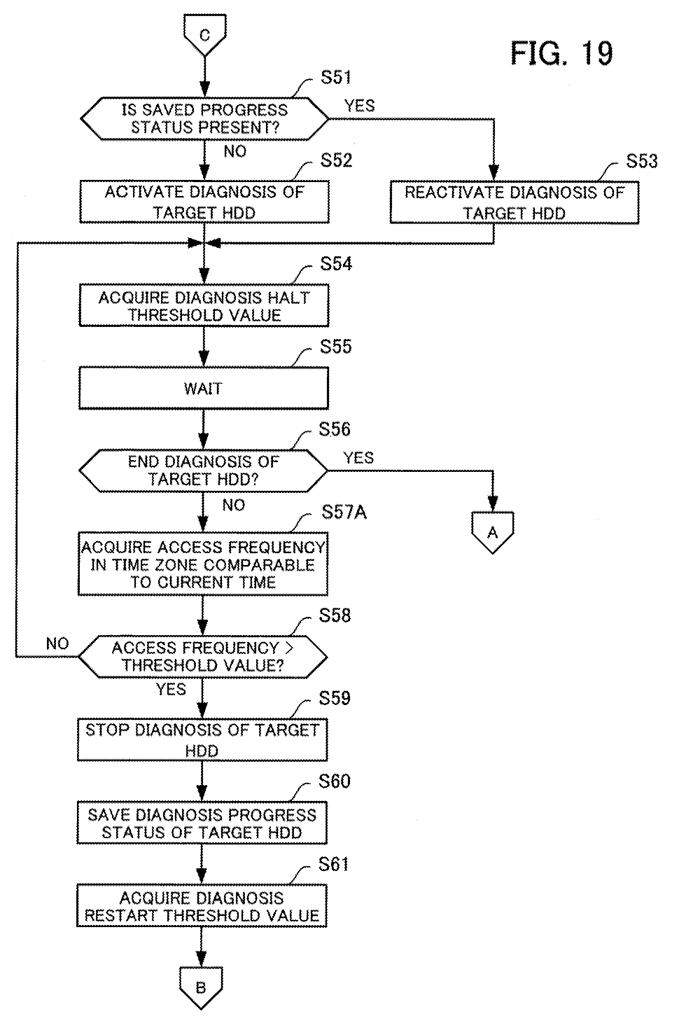

A third embodiment will now be described below with reference to FIGS. 18 to 21 illustrating diagnosis control processes. FIGS. 18 and 19 is a flowchart of a diagnosis control process (3) of the third embodiment.

In the third embodiment, the diagnosis control executed by the diagnosis control unit 114 includes a diagnosis control process (3) based on access frequency of the HDD 103, and a diagnosis control process (4) based on data transmission rate of the HDD 103. The diagnosis control unit 114 determines which of these two processes to use for each HDD 103, on the basis of diagnosis control data 223.

The diagnosis control process (3) is chosen when the diagnosis of a target HDD 103 is controlled on the basis of access frequencies. More specifically, the diagnosis control process (3) controls the diagnosis unit 115, so as not to interrupt the application executing unit 110 during its access to the HDD 103. The diagnosis control process (3) is invoked upon startup of the host computer 100 and is executed during the operation of the host computer 100.

The diagnosis control process (1) in the second embodiment decides when to start a diagnosis on the basis of history, and halts and restarts it on the basis of the current situation. The diagnosis control process (3) is different in that it decides the start, halt, and restart of a diagnosis, all on the basis of history.

The diagnosis control process (3) is different from the diagnosis control process (1) in that step S471 replaces steps S48 to S50, and step S57A replaces step S57, while the rest are the same. Accordingly, the following description will focus on these two steps S471 and S57A, without repeating previous explanations for the same steps.

[Step S471] The diagnosis control unit 114 acquires the current time, and acquires the access frequency in an access time zone that is comparable to the current time, from the access analyzing data 222, and proceeds to step S46. In this way, the diagnosis control process (3) executes history-based diagnosis control, not only at the start of diagnosis, but also at the halt and restart of the same.

[Step S57A] The diagnosis control unit 114 acquires the current time, and acquires the access frequency in the access time zone that is comparable to the current time, from the access analyzing data 222. For example, when the access history of the HDD 103 indicates a twenty-four hour cycle, the diagnosis control unit 114 acquires a record of access frequency of twenty-four hours earlier than the current time, for comparison with a threshold at the next step.

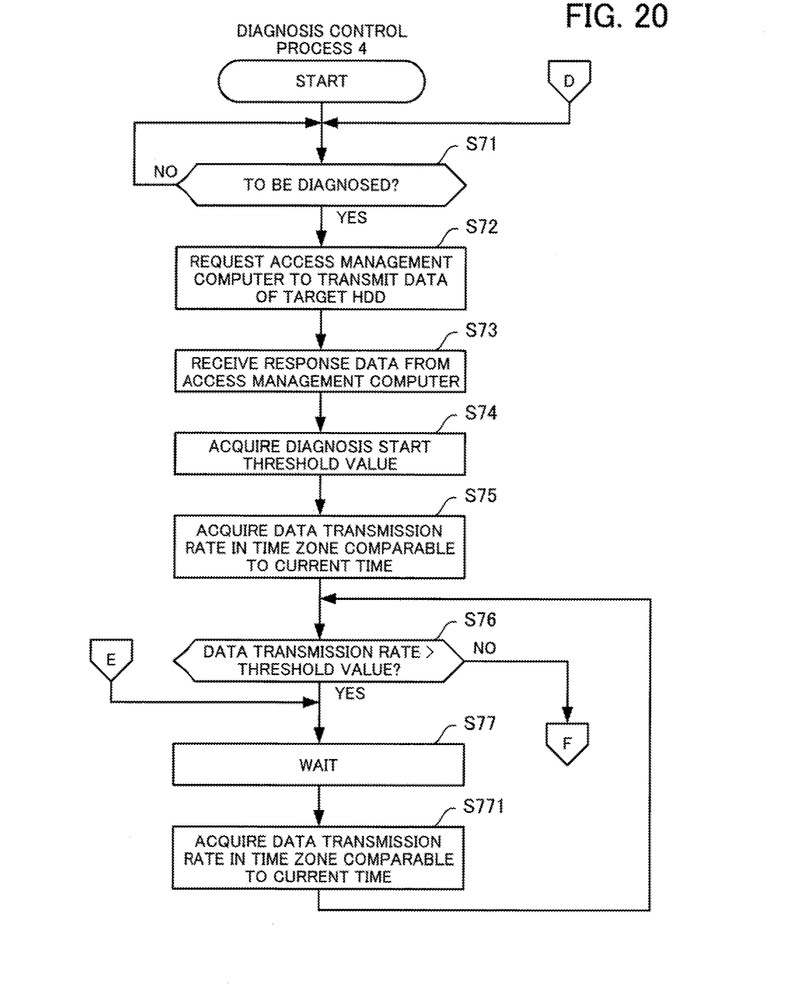

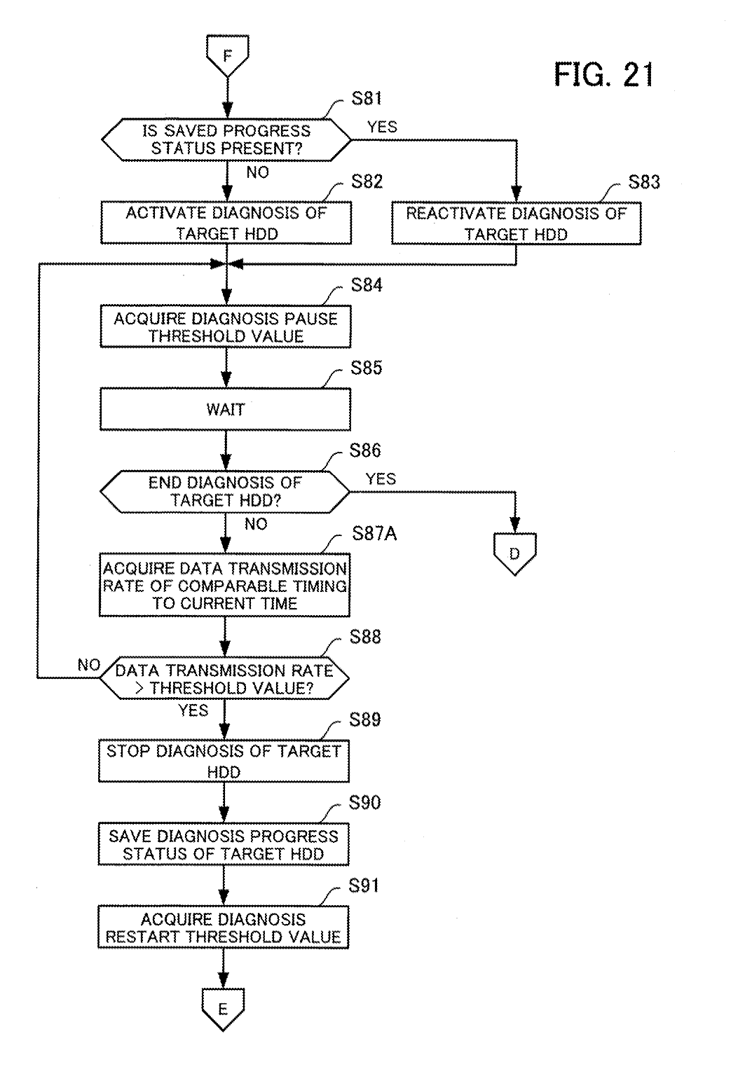

FIGS. 20 and 21 are a flowchart of the diagnosis control process (4) of the third embodiment. The diagnosis control process (4) is chosen when a diagnosis of a HDD 103 by the diagnosis unit 115 is controlled on the basis of data transmission rates. More specifically, the diagnosis control process (4) controls the diagnosis unit 115, so as not to interrupt the application executing unit 110 during its access to the HDD 103. The diagnosis control process (4) is invoked upon startup of the host computer 100, and is executed during the operation of the host computer 100.

Although, in the second embodiment, the diagnosis control process (2) decides a start of a diagnosis on the basis of history, and decides a halt and a restart of a diagnosis on the basis of the current situation, the diagnosis control process (4) is different in that the diagnosis control process (4) decides the start, halt, and restart of a diagnosis, all on the basis of history.

The diagnosis control process (4) is different in that step S771 replaces steps S78 to S80 of the diagnosis control process (2), and step S87A replaces step S87, while the rest are the same. Accordingly, the following description will focus on these two steps S771 and step S87A, without repeating previous explanations for the same steps.

[Step S771] The diagnosis control unit 114 acquires the current time, and acquires the data transmission rate in the access time zone that is comparable to the current time, from the access analyzing data 222, and proceeds to step S76. In this way, the diagnosis control process (4) controls a diagnosis on the basis of history not only at a start of diagnosis, but also at a halt and a restart.

[Step S87A] The diagnosis control unit 114 acquires the current time, and acquires the data transmission rate in the access time zone that is comparable to the current time, from the access analyzing data 222. For example, when the access history of the HDD 103 indicates a twenty-four hour cycle, the diagnosis control unit 114 acquires the data transmission rate of twenty-four hours earlier than the current time as a target for comparison.

In this way, the diagnosis control unit 114 controls the start, halt, and restart of a diagnosis of the target HDD 103. Also, the host computer 100 determines when to start, halt, and restart a diagnosis of the HDD 103 from its access history in the past, and thus eliminates the need for the time of monitoring access status of the HDD 103 before starting its diagnosis. Accordingly, the host computer 100 selects an appropriate time for starting a diagnosis of the HDD 103, without time lag. In this way, the host computer 100 keeps the HDD 103 from an excessive access load from the application executing unit 110, which repeats a periodical operation (for example, executes a predetermined process on a twenty-four hour cycle). Thereby, the host computer 100 efficiently diagnoses its HDD 103.

### Fourth Embodiment

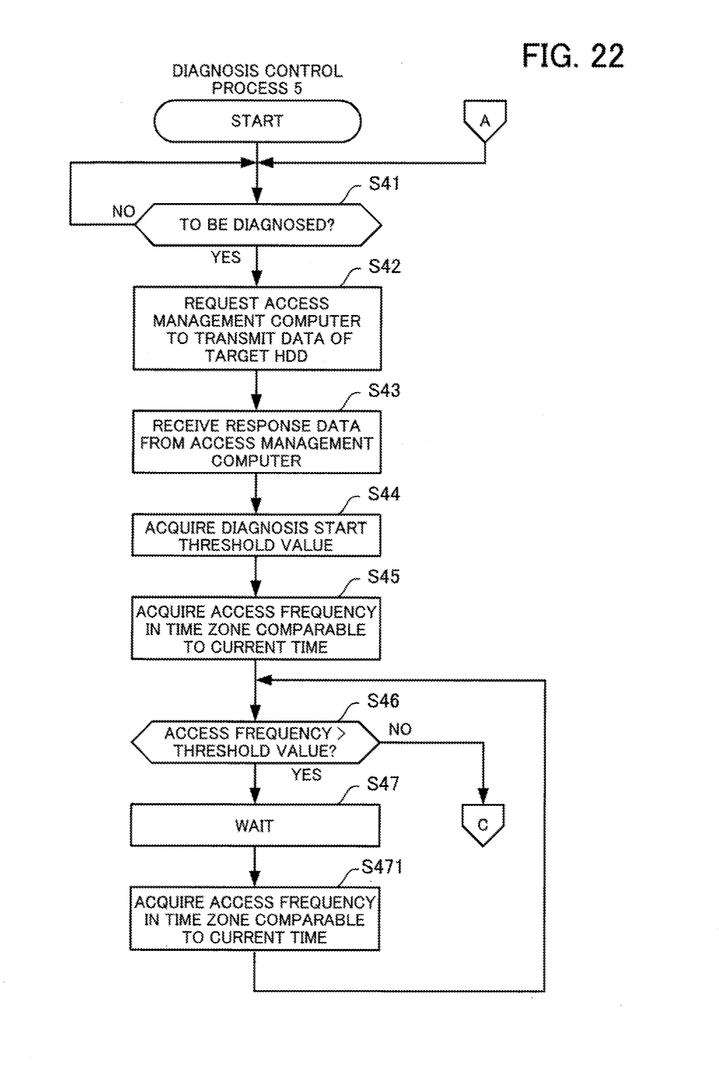

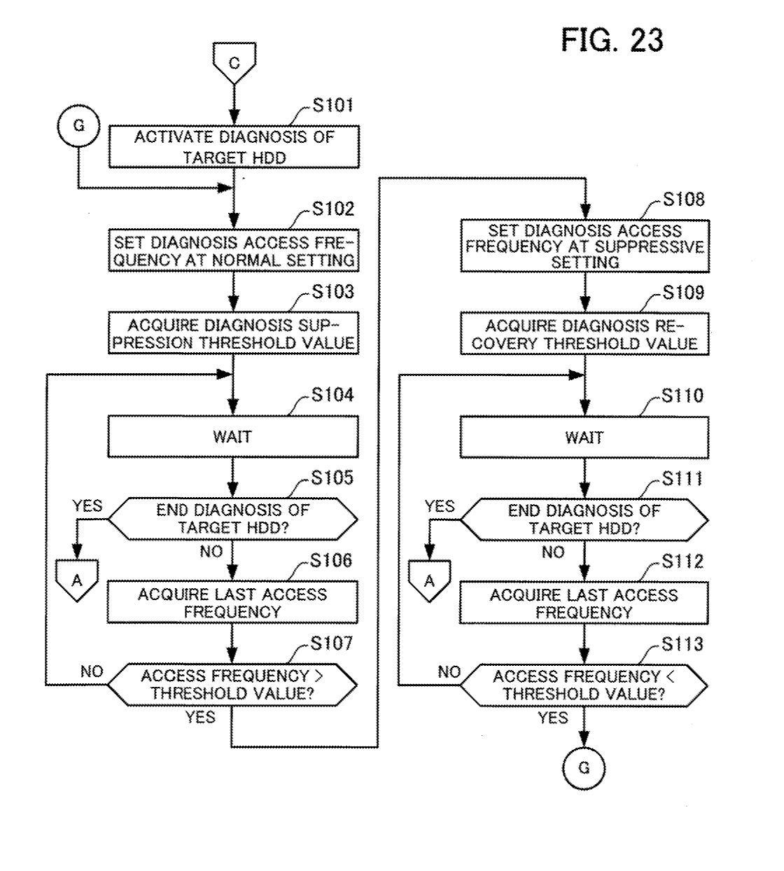

A fourth embodiment will now be described below with reference to FIGS. 22 to 25 illustrating diagnosis control processes. FIGS. 22 and 23 are a flowchart of a diagnosis control process (5) of the fourth embodiment.

In the fourth embodiment, the diagnosis control executed by the diagnosis control unit 114 includes the diagnosis control process (5) that controls a diagnosis on the basis of access frequency of a HDD 103, and the diagnosis control process (6) that controls a diagnosis on the basis of data transmission rate of a HDD 103. The diagnosis control unit 114 determines whether the diagnosis control is executed by the diagnosis control process (5) or the diagnosis control process (6), on the basis of diagnosis control data 223, for each HDD 103.

The diagnosis control process (5) is chosen when a diagnosis of a HDD 103 by the diagnosis unit 115 is controlled on the basis of access frequencies. More specifically, the diagnosis control process (5) controls the diagnosis unit 115, so as not to interrupt the application executing unit 110 during its access to the HDD 103. The diagnosis control process (5) is invoked upon startup of the host computer 100, and is executed during the operation of the host computer 100.

Although, in the third embodiment, the diagnosis control process (3) diagnoses with a non-adjustable access frequency to a HDD 103, the diagnosis control process (5) is different in that the diagnosis control process (5) suppresses an access frequency in diagnosis in response to a situation.

The diagnosis control process (5) is different from the diagnosis control process (3) in the process after an access frequency is determined to be equal to or lower than the threshold value in step S46. Accordingly, the following description will not repeat previous explanations for the same steps as the diagnosis control process (3), but will focus on the process in and after step S101.

[Step S101] The diagnosis control unit 114 instructs a diagnosis activation (diagnosis start) to the diagnosis unit 115.

[Step S102] The diagnosis control unit 114 sets an access frequency of a HDD 103 in the diagnosis, at a normal setting (for example, “1000 (1000 times/minute)”). Thereby, the diagnosis unit 115 executes the diagnosis of the HDD 103 with the access frequency at the normal setting.

[Step S103] The diagnosis control unit 114 acquires an access frequency threshold value for suppressing an access frequency in diagnosis (diagnosis suppression threshold value), from the diagnosis control data 223.

[Step S104] The diagnosis control unit 114 stands by for a wait time (for example, for one-minute analysis unit time), until a diagnosis end is determined.

[Step S105] The diagnosis control unit 114 determines whether or not the diagnosis of a target HDD 103 has ended. If the diagnosis has ended, the diagnosis control unit 114 proceeds to step S41, and awaits the next diagnosis start time. On the other hand, if the diagnosis has not ended, the diagnosis control unit 114 proceeds to step S106.

[Step S106] The diagnosis control unit 114 acquires the current time, and acquires the access frequency of the last access time zone from the access analyzing unit 113.

[Step S107] The diagnosis control unit 114 compares the access frequency acquired from the access analyzing unit 113, with the diagnosis suppression threshold value acquired in step S103. If the access frequency is higher than the diagnosis suppression threshold value, the diagnosis control unit 114 proceeds to step S108. If the access frequency is equal to or lower than the threshold value, the diagnosis control unit 114 proceeds to step S104.

[Step S108] The diagnosis control unit 114 sets an access frequency to the HDD 103 in the diagnosis at a suppressive setting (for example, 10% of the normal setting, or “100 (100 times/minute)”). Thereby, the diagnosis unit 115 executes a diagnosis of the HDD 103 with the access frequency at the suppressive setting.

[Step S109] The diagnosis control unit 114 acquires an access frequency threshold value for access frequency recovery in the diagnosis (diagnosis recovery threshold value), from the diagnosis control data 223.

[Step S110] The diagnosis control unit 114 stands by for a wait time (for example, for one-minute analysis unit time), until the diagnosis end is determined.

[Step S111] The diagnosis control unit 114 determines whether or not the diagnosis of the target HDD 103 has ended. If the diagnosis has ended, the diagnosis control unit 114 proceeds to step S41, and awaits the next diagnosis start time. On the other hand, if the diagnosis has not ended, the diagnosis control unit 114 proceeds to step S112.

[Step S112] The diagnosis control unit 114 acquires the current time, and acquires the access frequency of the last access time zone from the access analyzing unit 113.

[Step S113] The diagnosis control unit 114 compares the access frequency acquired from the access analyzing unit 113, with the diagnosis recovery threshold value acquired in step S109. If the access frequency is lower than the diagnosis recovery threshold value, the diagnosis control unit 114 proceeds to step S102. If the access frequency is equal to or higher than the threshold value, the diagnosis control unit 114 proceeds to step S110.

In this way, if the access frequency is higher than the diagnosis suppression threshold value, the diagnosis control unit 114 sets an access frequency in a diagnosis at a suppressive setting. If the access frequency is lower than the diagnosis recovery threshold value, the diagnosis control unit 114 sets an access frequency in a diagnosis at a normal setting.

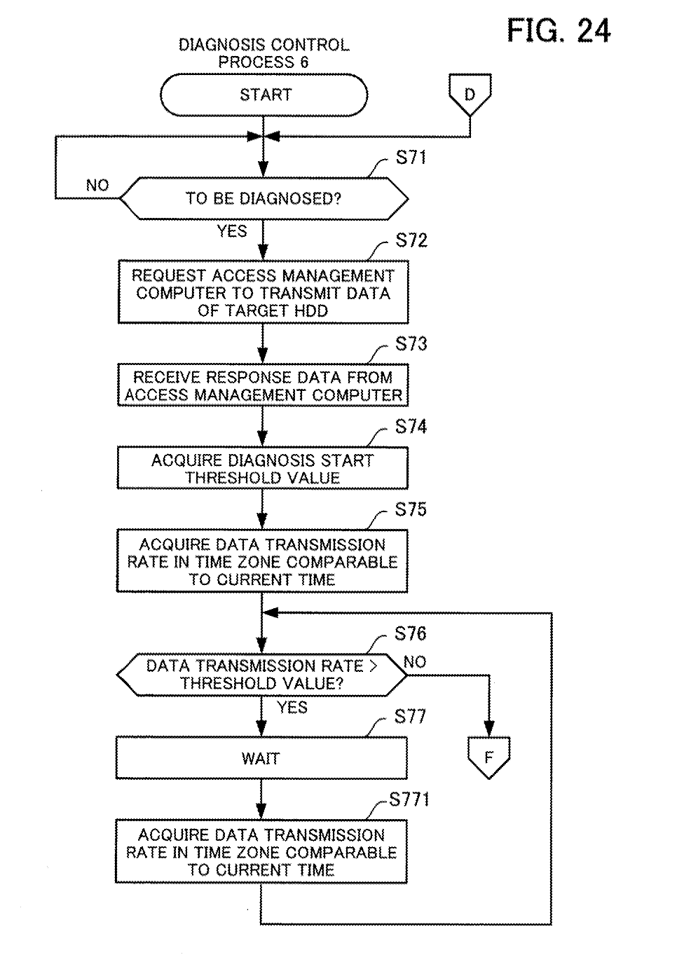

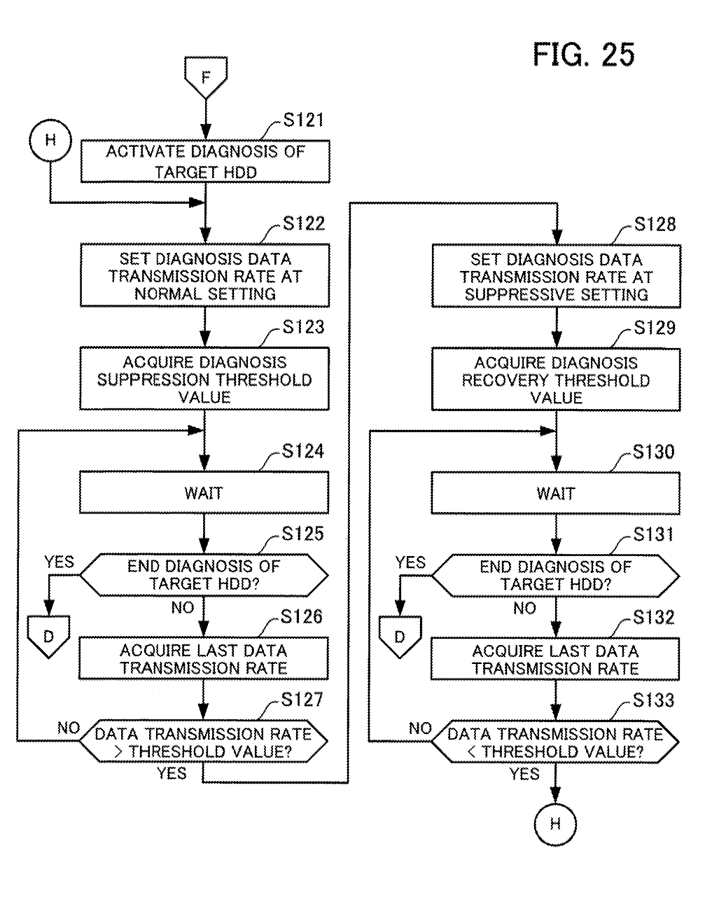

FIGS. 24 and 25 are a flowchart of the diagnosis control process (6) of the fourth embodiment. The diagnosis control process (6) is chosen when a diagnosis of a HDD 103 by the diagnosis unit 115 is controlled on the basis of data transmission rates. More specifically, the diagnosis control process (6) controls the diagnosis unit 115, so as not to interrupt the application executing unit 110 during its access to the HDD 103. The diagnosis control process (6) is invoked upon startup of the host computer 100, and is executed during the operation of the host computer 100.

Although, in the third embodiment, the diagnosis control process (4) diagnoses with a non-adjustable data transmission rate to a HDD 103, the diagnosis control process (6) is different in that the diagnosis control process (6) suppresses a data transmission rate in diagnosis in response to a situation.

The diagnosis control process (6) is different from the diagnosis control process (4) in the process after the data transmission rate is determined to be equal to or lower than the threshold value in step S76. Accordingly, the following description will not repeat previous explanations for the same steps as the diagnosis control process (4), but will focus on the process in and after step S121.

[Step S121] The diagnosis control unit 114 instructs a diagnosis activation (diagnosis start) to the diagnosis unit 115.

[Step S122] The diagnosis control unit 114 sets a data transmission rate to a HDD 103 in the diagnosis at a normal setting (for example, “1000 (MB/minute)”). Thereby, the diagnosis unit 115 executes a diagnosis of a HDD 103 with the data transmission rate at the normal setting.

[Step S123] The diagnosis control unit 114 acquires a data transmission rate threshold value for data transmission rate suppression in diagnosis (diagnosis suppression threshold value), from the diagnosis control data 223.

[Step S124] The diagnosis control unit 114 stands by for a wait time (for example, for one-minute analysis unit time), until the diagnosis end is determined.

[Step S125] The diagnosis control unit 114 determines whether or not a diagnosis of a HDD 103 that is to be diagnosed has ended. If the diagnosis has ended, the diagnosis control unit 114 proceeds to step S71, and awaits the next diagnosis start time. On the other hand, if the diagnosis has not ended, the diagnosis control unit 114 proceeds to step S126.

[Step S126] The diagnosis control unit 114 acquires the current time, and acquires the data transmission rate of the last access time zone from the access analyzing unit 113.

[Step S127] The diagnosis control unit 114 compares the data transmission rate acquired from the access analyzing unit 113, with the diagnosis suppression threshold value acquired in step S123. If the data transmission rate is higher than the diagnosis suppression threshold value, the diagnosis control unit 114 proceeds to step S128. If the data transmission rate is equal to or lower than the threshold value, the diagnosis control unit 114 proceeds to step S124.

[Step S128] The diagnosis control unit 114 sets a data transmission rate to the HDD 103 in diagnosis at a suppressive setting (for example, 50% of the normal setting, or “500 (MB/minute)”). Thereby, the diagnosis unit 115 executes a diagnosis of the HDD 103 with the data transmission rate at the suppressive setting.

[Step S129] The diagnosis control unit 114 acquires a data transmission rate threshold value for data transmission rate recovery in diagnosis (diagnosis recovery threshold value), from the diagnosis control data 223.

[Step S130] The diagnosis control unit 114 stands by for a wait time (for example, for one-minute analysis unit time), until the diagnosis end is determined.

[Step S131] The diagnosis control unit 114 determines whether or not a diagnosis of the target HDD 103 has ended. If the diagnosis has ended, the diagnosis control unit 114 proceeds to step S71, and awaits the next diagnosis start time. On the other hand, if the diagnosis has not ended, the diagnosis control unit 114 proceeds to step S132.

[Step S132] The diagnosis control unit 114 acquires the current time, and acquires the data transmission rate of the last access time zone from the access analyzing unit 113.

[Step S133] The diagnosis control unit 114 compares the data transmission rate acquired from the access analyzing unit 113, with the diagnosis recovery threshold value acquired in step S129. If the data transmission rate is lower than the diagnosis recovery threshold value, the diagnosis control unit 114 proceeds to step S122. If the data transmission rate is equal to or higher than the threshold value, the diagnosis control unit 114 proceeds to step S130.

In this way, if the data transmission rate is higher than the diagnosis suppression threshold value, the diagnosis control unit 114 sets a data transmission rate in a diagnosis at a suppressive setting. If the access frequency is lower than the diagnosis recovery threshold value, the diagnosis control unit 114 sets a data transmission rate in a diagnosis at a normal setting.

As described above, the diagnosis control unit 114 dynamically changes the access load on a HDD 103 in the diagnosis of the HDD 103. In this way, the host computer 100 keeps a HDD 103 from an excessive access load from the application executing unit 110, while also efficiently executing the diagnosis of the HDD 103.

### Variation of Fourth Embodiment

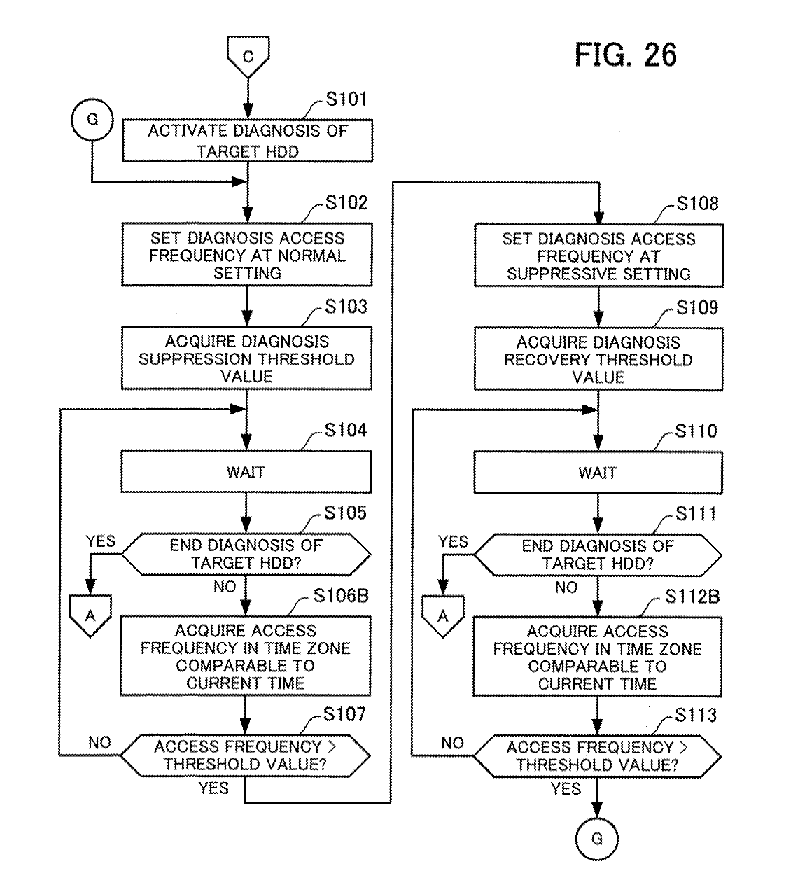

A variation of the diagnosis control process of the fourth embodiment will now be described below with reference to FIG. 26. FIG. 26 is a flowchart of a variation of the diagnosis control process (5) of the fourth embodiment.

This variation includes steps S106B and S112B that replace steps S106 and S112 of the original diagnosis control process (5), respectively.

[Step S106B], [Step S112B] The diagnosis control unit 114 acquires an access frequency in the access time zone that is comparable to the current time, from the access analyzing data 222.

In this way, when the access load pattern to a HDD 103 from the application executing unit 110 is cyclic and has no or little difference between cycles, the host computer 100 can control the access load only by history. Since the current access load is needless to be monitored, the host computer 100 executes a diagnosis without a time lag.

Although the variation of the diagnosis control process (5) of the fourth embodiment has been described, the diagnosis control process (6) of the fourth embodiment can be varied in the same manner.

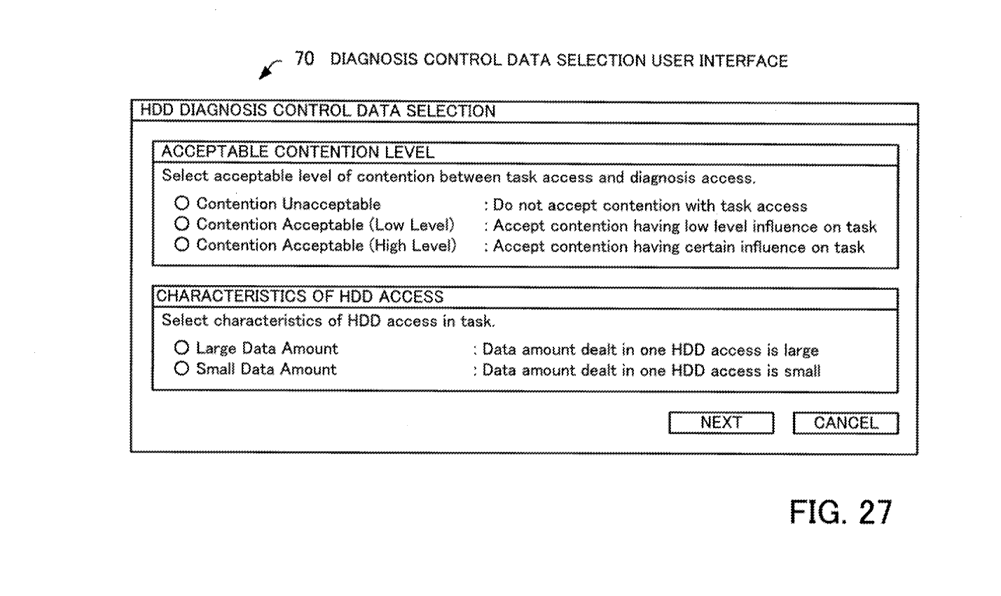

Next, with reference to FIGS. 27 to 34, the following description will explain setting of diagnosis control data 223 for allowing each host computer 100 to efficiently execute a diagnosis with a reduced influence on the application executing unit 110. FIGS. 27 to 34 illustrate examples of diagnosis control data selection user interfaces of the fourth embodiment.

The diagnosis control data 223 is to reduce the influence on the application executing unit 110, and to efficiently execute a diagnosis. Hence, each host computer 100 sets diagnosis control data 223 according to access characteristics to a HDD 103 from the application executing unit 110.

Each host computer 100 provides a diagnosis control data selection user interface for setting diagnosis control data 223. For example, each host computer 100 displays the diagnosis control data selection user interface on a monitor 11, and accepts input operation of a user from a mouse 13, in order to set diagnosis control data 223. Note that diagnosis control data 223 may be set by the diagnosis control unit 114, or by a setting unit which is provided separately.

The diagnosis control data selection user interface 70 illustrated in FIG. 27 prompts the user to make a choice for two items of “acceptable contention level” and “characteristics of HDD access”. The item “acceptable contention level” is to set how much contention between the application executing unit 110 (task access) and the diagnosis unit 115 (HDD diagnosis) is acceptable for the HDD 103 that is to be diagnosed. The setting options for “acceptable contention level” (acceptable contention level setting information) include “contention unacceptable”, “contention acceptable (low level)”, and “contention acceptable (high level)”. Option “contention unacceptable” does not accept contention between task access and HDD diagnosis. Option “contention acceptable (low level)” accepts contention between task access and HDD diagnosis when its influence on task access is small. Option “contention acceptable (high level)” accepts contention between task access and HDD diagnosis when its influence on task access is not significant.

For example, when the application executing unit 110 executes a task whose real-time processing performance is important, the response delay due to access contention has a large influence on the task, and therefore “contention unacceptable” is selected. The tasks of this type include, for example, online processing such as securities trading and the like. Candidates for diagnosis control data presented upon selection of “contention unacceptable” include those that permit diagnosis when there is no task access to HDDs 103.

Also, when the application executing unit 110 executes a task whose real-time processing performance is not important to the extent that a temporary response delay of task access is acceptable, “contention acceptable (low level)” is selected. Candidates for diagnosis control data presented upon selection of “contention acceptable (low level)” include those that permit diagnosis when task access to a HDD 103 is lower than a certain level. Hence, candidates for diagnosis control data presented upon selection of “contention acceptable (low level)” include those that halt and restart diagnosis in response to a task access level from the application executing unit 110.

Also, when the application executing unit 110 executes a task which widely accepts a response delay of task access, “contention acceptable (high level)” is selected. The task which widely accepts a response delay of task access is, for example, a non-urgent task such as a data backup process. Candidates for diagnosis control data presented upon selection of “contention acceptable (high level)” include those that adjust a load on a HDD 103 from the diagnosis unit 115 in response to task access to the HDD 103. Hence, candidates for diagnosis control data presented upon selection of “contention acceptable (high level)” include those that suppress and recover diagnosis in response to a task access level of the application executing unit 110.

The item “characteristics of HDD access” is to set access characteristics to a HDD 103 from the application executing unit 110 (task access). The setting options of “characteristics of HDD access” (access characteristics setting information) includes “large data amount” and “small data amount”. The “large data amount” indicates that a data amount dealt in one access to a HDD 103 is larger than a predetermined amount. The “small data amount” indicates that a data amount dealt in one access to a HDD 103 is smaller than a predetermined amount. The “characteristics of HDD access” may be a rigorous determination of the data amount by a specific threshold value, or may be a rough determination of the data amount by the subjective view of a user.

For example, when the data amount dealt in one task access from the application executing unit 110 is large, “large data amount” is selected. Candidates for diagnosis control data presented upon selection of “large data amount” are mainly “data transmission rates (transmission rate)”, which is an index of an access load on a HDD 103. Also, when the data amount dealt in one task access from the application executing unit 110 is small, “small data amount” is selected. Candidates for diagnosis control data presented upon selection of “small data amount” are mainly “access frequency”, which is an index of an access load on a HDD 103. In this way, the host computer 100 flexibly controls the diagnosis of a HDD 103 in response to characteristics of the application executing unit 110.

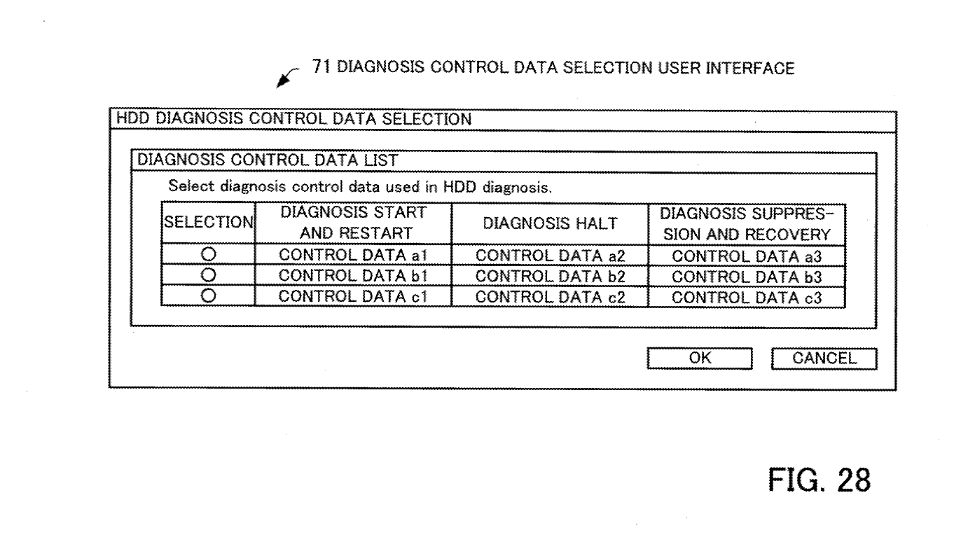

When the host computer 100 accepts a click on the “next” button while both options of “acceptable contention level” and “characteristics of HDD access” are selected, the host computer 100 displays a diagnosis control data selection user interface 71 illustrated in FIG. 28. When the host computer 100 accepts a click on a “cancel” button, the host computer 100 cancels setting of two items “acceptable contention level” and “characteristics of HDD access”.

The diagnosis control data selection user interface 71 prompts a user to selectively input one item of “diagnosis control data list”. The item “diagnosis control data list” is to set diagnosis control data used in diagnosis of a target HDD 103. The “diagnosis control data list” presents a plurality of setting options (diagnosis control information) that include specific numerical values that are used in “diagnosis start and restart”, “diagnosis halt”, and “diagnosis suppression and recovery”.

When the host computer 100 accepts a click on a “OK” button while an option of “diagnosis control data list” is selected, the host computer 100 completes setting of diagnosis control data 223. When the host computer 100 accepts a click on a “cancel” button, the host computer 100 cancels setting of “diagnosis control data list”.

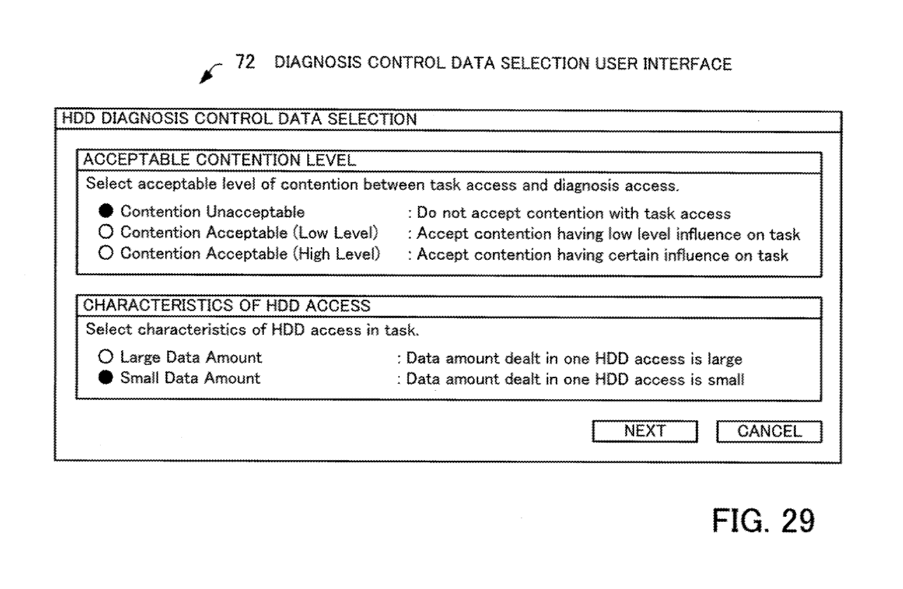

The diagnosis control data selection user interface 72 illustrated in FIG. 29 presents a state in which “contention unacceptable” is selected as the setting of “acceptable contention level” and “small data amount” is selected as the setting of “characteristics of HDD access”. The host computer 100 decides the options of “diagnosis control data list” on the basis of the settings of “acceptable contention level” and “characteristics of HDD access”.

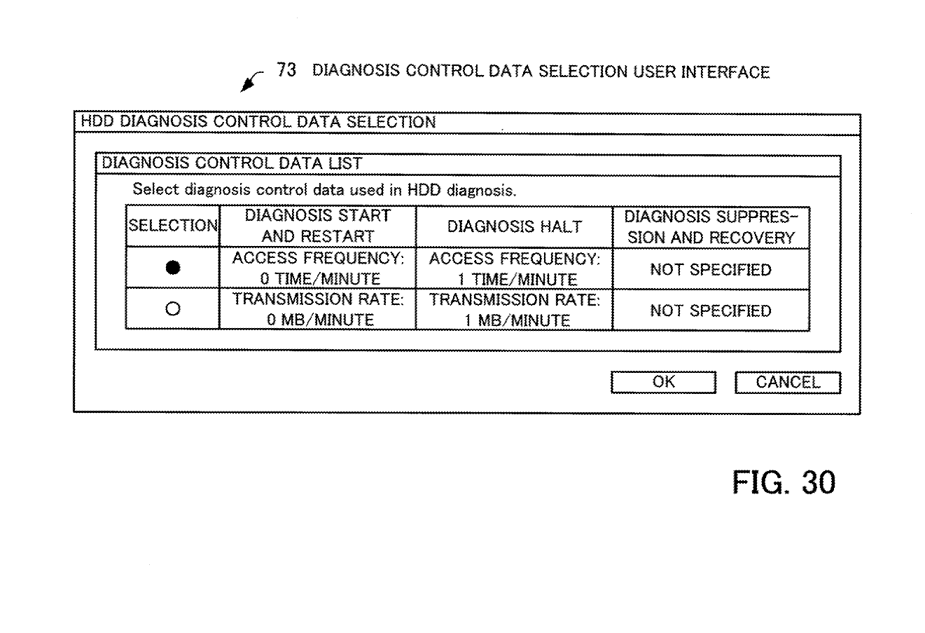

The diagnosis control data selection user interface 73 illustrated in FIG. 30 presents a state in which the decided options are presented and a selection input of a presented option is accepted. The diagnosis control data selection user interface 73 presents two options in “diagnosis control data list”, in response to the accepted settings of “acceptable contention level; contention unacceptable” and “characteristics of HDD access; small data amount”. The first option is “diagnosis start and restart; access frequency: 0 time/minute”, “diagnosis halt; access frequency: 1 time/minute”, and “diagnosis suppression and recovery; not specified”. The second option is “diagnosis start and restart; transmission rate: 0 MB/minute”, “diagnosis halt; transmission rate: 1 MB/minute”, and “diagnosis suppression and recovery; not specified”. The diagnosis control data selection user interface 73 presents a state in which the first option is selected.

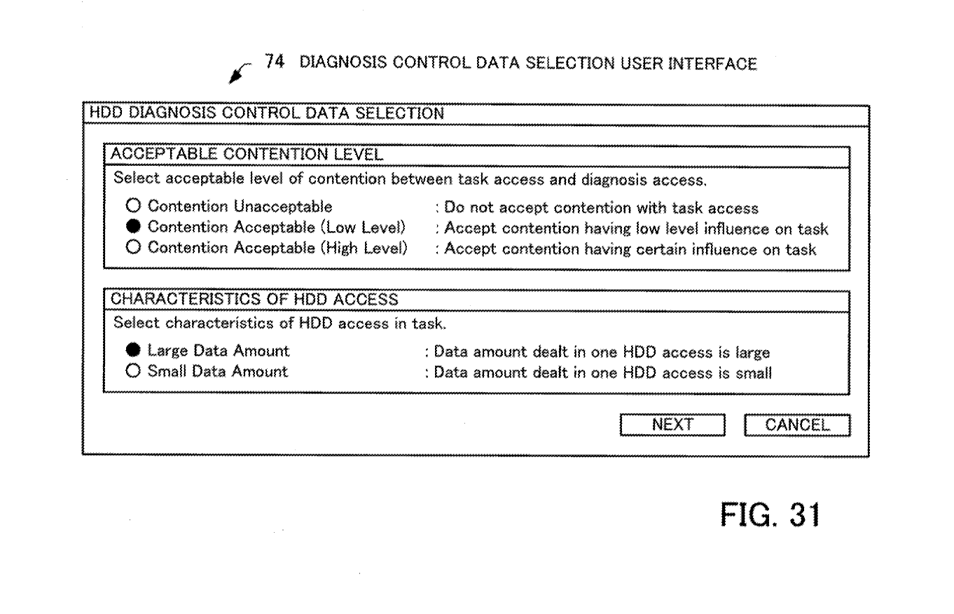

The diagnosis control data selection user interface 74 illustrated in FIG. 31 presents a state in which “contention acceptable (low level)” is selected as the setting of “acceptable contention level” and “large data amount” is selected as the setting of “characteristics of HDD access”. The host computer 100 decides the options of “diagnosis control data list” on the basis of the settings of “acceptable contention level” and “characteristics of HDD access”.

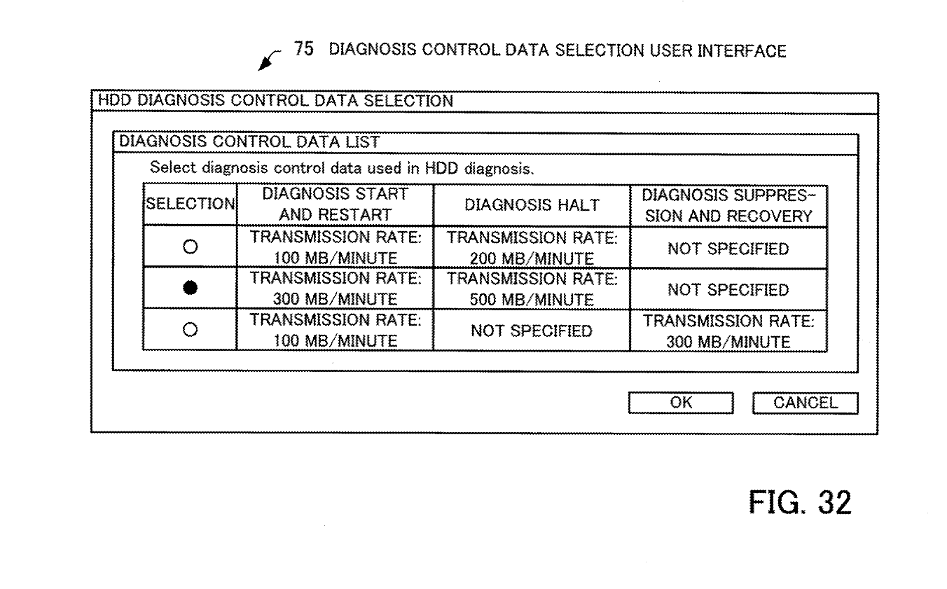

The diagnosis control data selection user interface 75 illustrated in FIG. 32 presents a state in which the decided options are listed and a selection input of a presented option is accepted. The diagnosis control data selection user interface 75 presents three options in “diagnosis control data list”, in response to the accepted settings of “acceptable contention level; contention acceptable (low level)” and “characteristics of HDD access; large data amount”. The first option is “diagnosis start and restart; transmission rate: 100 MB/minute”, “diagnosis halt; transmission rate: 200 MB/minute”, and “diagnosis suppression and recovery; not specified”. The second option is “diagnosis start and restart; transmission rate: 300 MB/minute”, “diagnosis halt; transmission rate: 500 MB/minute”, and “diagnosis suppression and recovery; not specified”. The third option is “diagnosis start and restart; transmission rate: 100 MB/minute”, “diagnosis halt; not specified”, and “diagnosis suppression and recovery; transmission rate: 300 MB/minute”. The diagnosis control data selection user interface 75 presents a state in which the second option is selected.

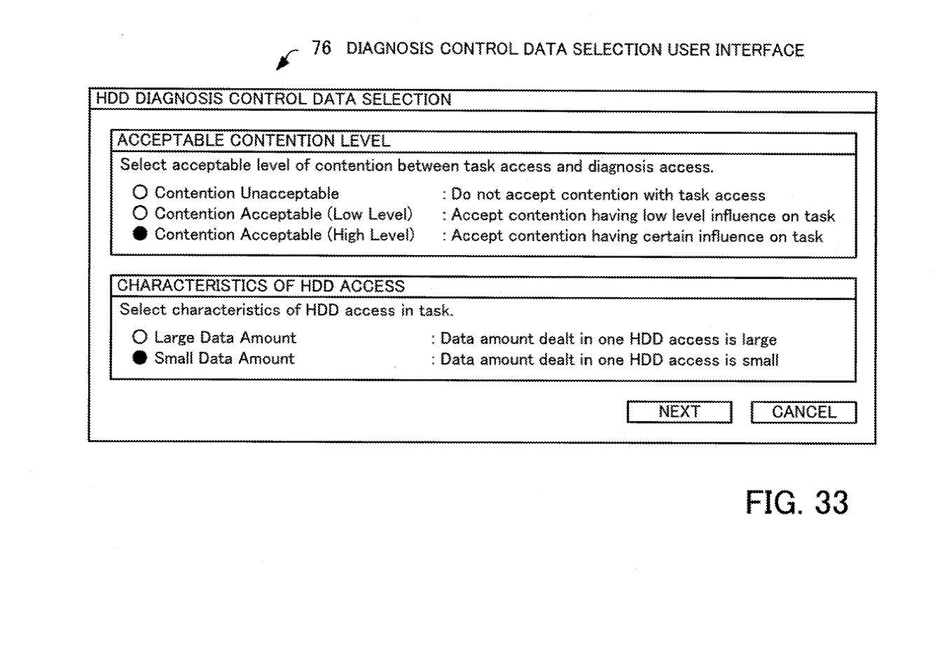

The diagnosis control data selection user interface 76 illustrated in FIG. 33 presents a state in which “contention acceptable (high level)” is selected as the setting of “acceptable contention level” and “small data amount” is selected as the setting of “characteristics of HDD access”. The host computer 100 decides the options of “diagnosis control data list” on the basis of the settings of “acceptable contention level” and “characteristics of HDD access”.

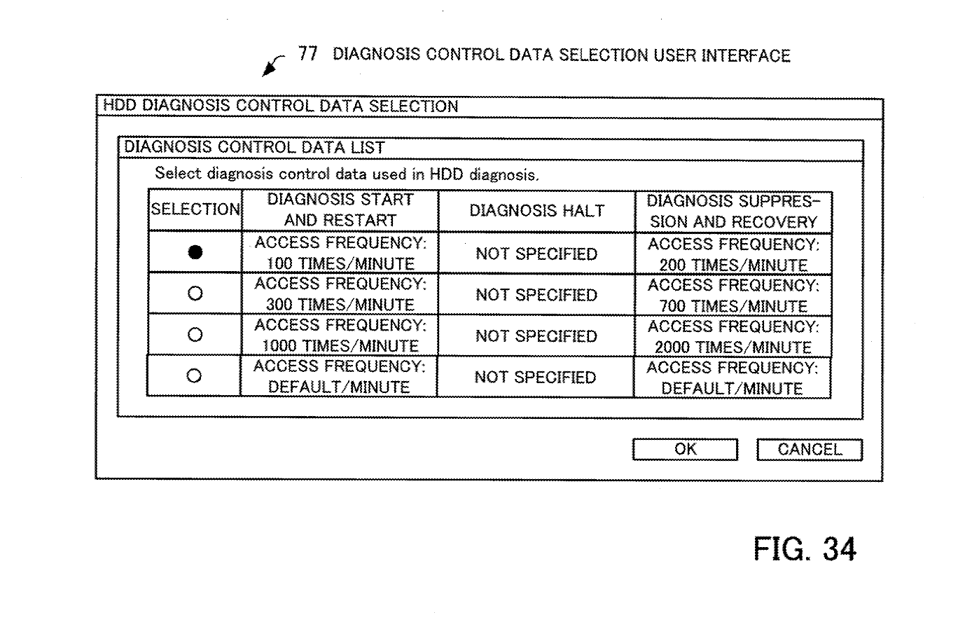

The diagnosis control data selection user interface 77 illustrated in FIG. 34 presents a state in which the decided options are presented and a selection input of a presented option is accepted. The diagnosis control data selection user interface 77 presents four options in “diagnosis control data list” in response to the accepted settings of “acceptable contention level; contention acceptable (high level)” and “characteristics of HDD access; small data amount”. The first option is “diagnosis start and restart; access frequency: 100 times/minute”, “diagnosis halt; not specified”, and “diagnosis suppression and recovery; access frequency: 200 times/minute”. The second option is “diagnosis start and restart; access frequency: 300 times/minute”, “diagnosis halt; not specified”, and “diagnosis suppression and recovery; access frequency: 700 times/minute”. The third option is “diagnosis start and restart; access frequency: 1000 times/minute”, “diagnosis halt; not specified”, and “diagnosis suppression and recovery; access frequency: 2000 times/minute”. The fourth option is “diagnosis start and restart; access frequency: default/minute”, “diagnosis halt; not specified”, and “diagnosis suppression and recovery; access frequency: default/minute”. The diagnosis control data selection user interface 77 presents a state in which the first option is selected.

### Fifth Embodiment

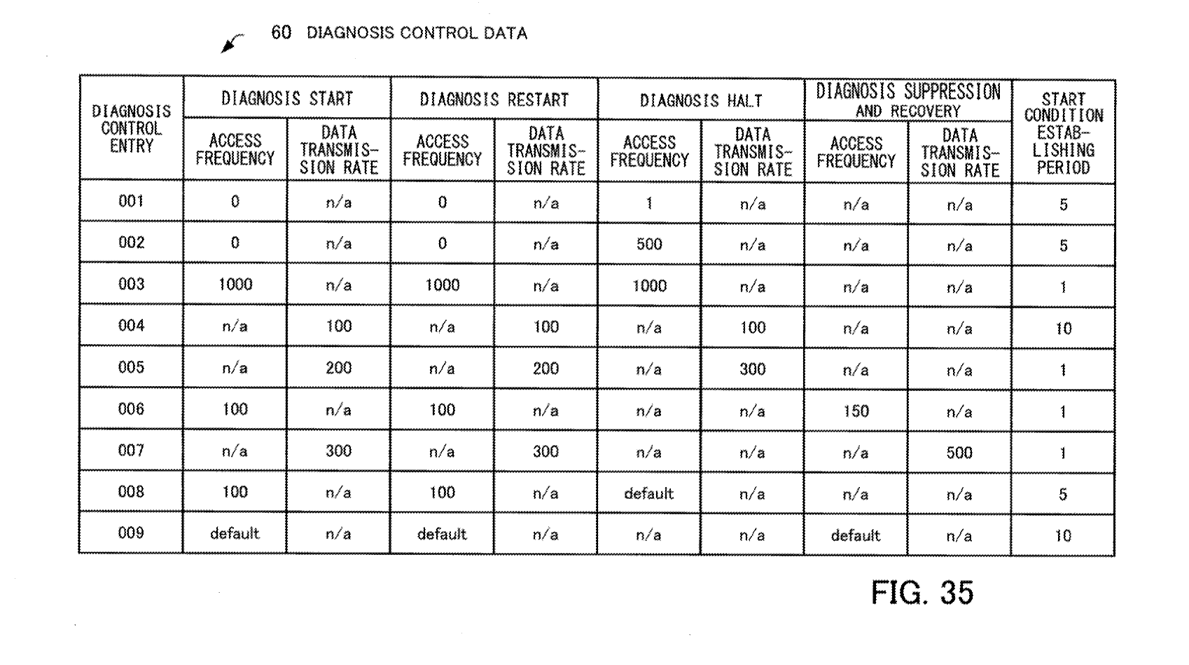

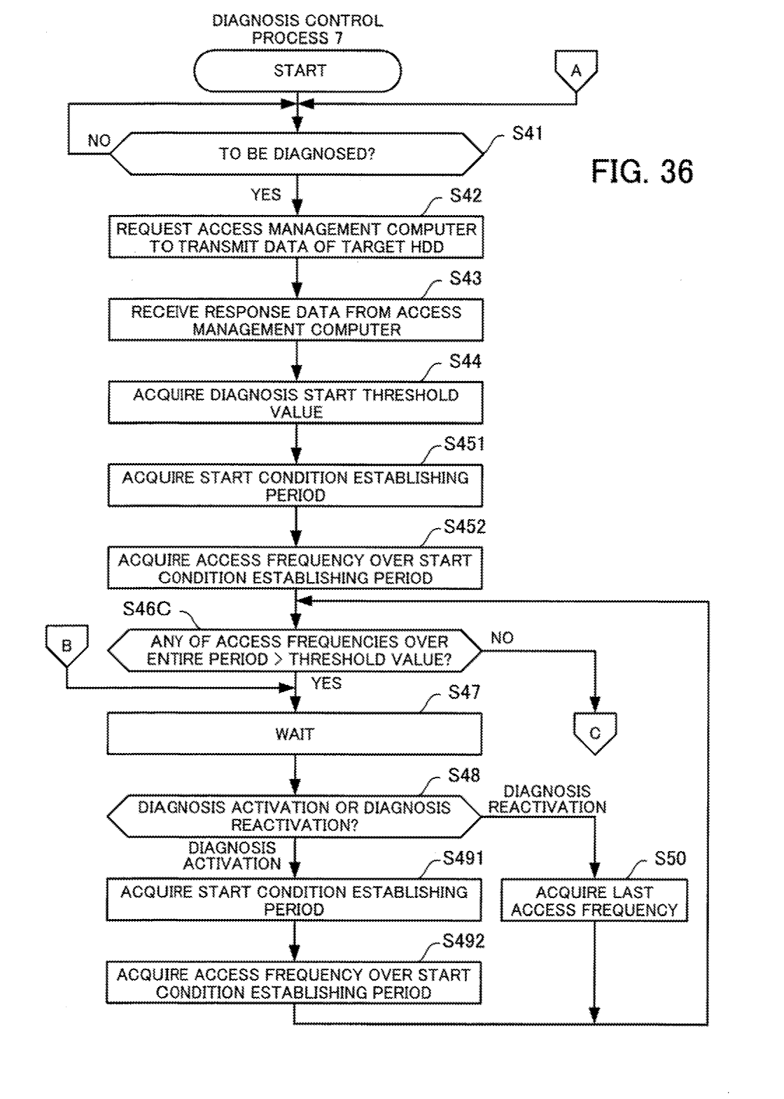

A fifth embodiment will now be described below with reference to FIGS. 35 and 36 illustrating a diagnosis control process. FIG. 35 illustrates an example of diagnosis control data of the fifth embodiment.

The diagnosis control process (7) (refer to FIG. 36) is chosen when a diagnosis of a HDD 103 by the diagnosis unit 115 is controlled on the basis of access frequencies. More specifically, the diagnosis control process (7) controls the diagnosis unit 115, so as not to interrupt the application executing unit 110 during its access to the HDD 103. The diagnosis control process (7) is invoked upon startup of the host computer 100, and is executed during the operation of the host computer 100.

Although the diagnosis control process (1) in the second embodiment decides a start of diagnosis on the basis of history corresponding to the current time, the diagnosis control process (7) is different in that the diagnosis control process (7) decides a start of diagnosis on the basis of history corresponding to a certain period starting from the current time.

Also, although the diagnosis control process (1) in the second embodiment controls a diagnosis on the basis of the diagnosis control data 223 which is the diagnosis control data 58, the diagnosis control process (7) controls a diagnosis on the basis of the diagnosis control data 223 which is the diagnosis control data 60. The diagnosis control data 60 includes diagnosis control entries of each HDD 103. The diagnosis control data 60 includes access frequency threshold values and transmission rate threshold values, for determining “diagnosis start”, “diagnosis restart”, “diagnosis halt”, “diagnosis suppression and recovery”, with respect to each diagnosis control entry. Further, the diagnosis control data 60 includes “start condition establishing period” with respect to each diagnosis control entry. The “start condition establishing period” is a duration during which a start condition continues being established after “diagnosis start” is determined. For example, the HDD 103 corresponding to the diagnosis control entry “001” requests that the access frequency “0 (times/minute)” continue being established for “5 (minutes)”.

FIG. 36 is a flowchart of the diagnosis control process (7) of the fifth embodiment. The diagnosis control process (7) is different from the diagnosis control process (1) in that steps S451 and S452 replace step S45, and steps S491 and S492 replace step S49. Further, step S46C of the diagnosis control process (7) replaces step S46 of the diagnosis control process (1), while the rest are the same. Accordingly, the description will focus on these steps S451, S452, S46C, S491, and S492, without repeating previous explanations for the same steps.

[Step S451] The diagnosis control unit 114 acquires the current time, and acquires a start condition establishing period from the diagnosis control data 223 (60).

[Step S452] The diagnosis control unit 114 acquires a start-condition-establishing-period amount of access frequencies in the access time zone that is comparable to the period starting from the current time and continuing over the start condition establishing period, from the access analyzing data 222. For example, when the access history of a HDD 103 indicates a twenty-four hour cycle, the diagnosis control unit 114 acquires access frequencies of the period starting from twenty-four hours earlier than the current time and continuing over the start condition establishing period, as a target for comparison.

[Step S46C] The diagnosis control unit 114 compares the access frequencies over the start condition establishing period acquired from the access analyzing data 222, with the threshold value. If any of the access frequencies in the acquired access time zone is higher than the threshold value, the diagnosis control unit 114 proceeds to step S47. If all of the access frequencies of the acquired access time zone are equal to or lower than the threshold value, the diagnosis control unit 114 proceeds to step S51.

[Step S491] The diagnosis control unit 114 acquires the current time, and acquires a start condition establishing period from the diagnosis control data 223 (60).

[Step S492] The diagnosis control unit 114 acquires a start-condition-establishing-period amount of access frequencies in the access time zone that is comparable to the period starting from the current time and continuing over the start condition establishing period, from the access analyzing data 222.

Although, in the fifth embodiment, the diagnosis control executed by the diagnosis control unit 114 is described with respect to only the diagnosis control process (7) that controls a diagnosis on the basis of access frequencies of a HDD 103, the diagnosis control process that controls a diagnosis on the basis of data transmission rates of a HDD 103 may be implemented in the same manner, by using data transmission rates as diagnosis reference information in place of access frequencies. Thus, such description is omitted.

In this way, the diagnosis control unit 114 controls the start of a diagnosis of a target HDD 103. Also, the host computer 100 determines when to start a diagnosis of a HDD 103 from its history of access frequencies during the period starting from the current time and continuing over the start condition establishing period, and thus the diagnosis is more likely to continue without a halt during a certain period having a length of the start condition establishing period. Accordingly, the host computer 100 selects an appropriate time for diagnosis of a HDD 103, and controls a diagnosis without a time lag at the time of a diagnosis halt and a diagnosis restart. Thereby, the host computer 100 efficiently diagnoses a HDD 103.

Although, in the fifth embodiment, the diagnosis control executed by the diagnosis control unit 114 determines the start of a diagnosis on the basis of access history over a predetermined period, the diagnosis control is not limited thereto. The halt, restart, suppression, and recovery of diagnosis may be determined on the basis of access history over a predetermined period.

### Sixth Embodiment

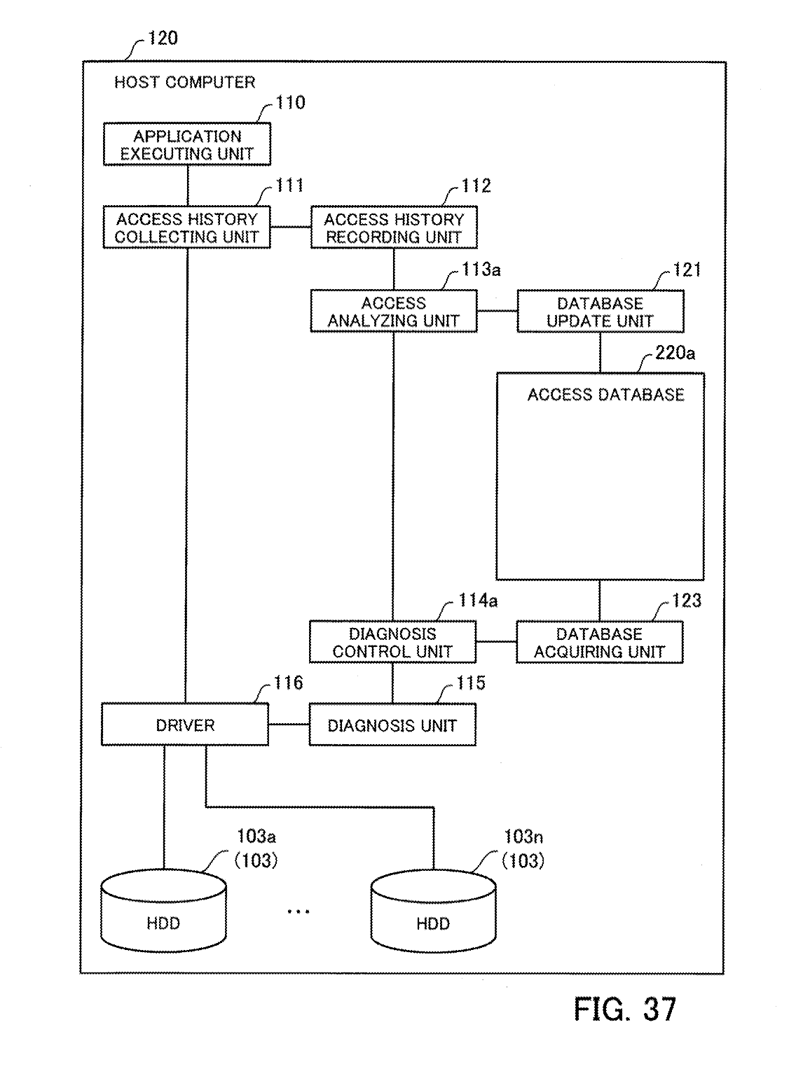

A sixth embodiment will now be described below, with reference to FIG. 37 illustrating a host computer configuration. FIG. 37 illustrates an exemplary configuration of host computers of the sixth embodiment.

The host computer 120 has a separate access database 220a, unlike the host computer 100 of the second embodiment that leaves the management of the access database 220 to the access management computer 200. Note that the following description for the host computer 120 will not repeat previous explanations for the same components as the host computer 100 of the second embodiment, using the same reference signs for those components.

The host computer 120 is equipped with HDDs 103 that is to be diagnosed, and accesses the HDDs 103 in response to a request from an application as appropriate. The host computer 120 includes an application executing unit 110, an access history collecting unit 111, an access history recording unit 112, an access analyzing unit 113a, a diagnosis control unit 114a, a diagnosis unit 115, a driver 116, and HDDs 103 (103a, . . . , 103n). In addition, the host computer 120 includes a database update unit 121, a data retrieving unit 123, and an access database 220a.

The access analyzing unit 113a analyzes the access history recorded by the access history recording unit 112. The access analyzing unit 113a notifies the database update unit 121 of a calculated access frequency and a data transmission rate of each time interval, as an analysis result (access analyzing data). Also, the access analyzing unit 113a notifies the database update unit 121 of the access history of each HDD 103 in addition to the analysis result of the same.

The database update unit 121 updates the access database 220a with the data sent from the access analyzing unit 113a. The data retrieving unit 123 acquires data from the access database 220a on the basis of a request from the diagnosis control unit 114a. The access database 220a is a database that stores information such as access histories of the HDDs 103 diagnosed by the host computer 120. The data in the access database 220a is same as the data in the access database 220, except that the data in the access database 220a is limited to the data of a host computer 120.

The diagnosis control unit 114a controls the diagnosis unit 115 that executes the diagnosis of the HDDs 103. The diagnosis control unit 114a controls the diagnosis unit 115 on the basis of access histories of the HDDs 103 and their analysis results acquired from the access database 220a via the data retrieving unit 123, as well as analysis results obtained from the access analyzing unit 113a.

Note that the above processing functions may be realized by computers that are installed with programs describing functional procedures of the information processing apparatus 1, the host computer 100, 120, and the access management computer 200. Executing the programs in these computers realizes the above processing functions. The programs describing the procedures may be recorded on a computer-readable recording medium. The computer-readable recording medium is such as a magnetic storage device, an optical disc, a magneto-optical recording medium, and a semiconductor memory. The magnetic storage device is such as a hard disk drive (HDD), a flexible disk (FD), and a magnetic tape. The optical disc is such as a DVD, a DVD-RAM, and a CD-ROM/RW. The magneto-optical recording medium is such as a magneto-optical disk (MO).

The programs may be sold in the market in the form of a portable recording medium, such as a DVD and a CD-ROM, on which the programs are recorded, for example. Also, the programs may be stored in a storage device of a server computer, and transmitted via a network from the server computer to another computer.

For example, a computer stores a program recorded on a portable recording medium or transmitted from a server computer, in a storage device of the computer. Then, the computer reads the program from the storage device, and executes a process in accordance with the program. Note that the computer may directly read the program from the portable recording medium to execute the process in accordance with the program. Also, the computer may execute a process in accordance with a program, each time the computer receives the program transmitted from the server computer via a network.

Also, at least a part of the above processing function can be realized by an electronic circuit such as a DSP (Digital Signal Processor), an ASIC (Application Specific Integrated Circuit), and a PLD (Programmable Logic Device).

According to one aspect, the diagnosis of a information recording device is efficiently executed in an information processing apparatus, an access control program, and an access control method.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. An information processing apparatus comprising a processor configured to perform a procedure including:
detecting access status of an information recording device and forming the detected access status into access records at predetermined time intervals;
generating history information from the access records that have been formed over a predetermined period;
selecting at least one of the access records that has a predetermined relationship with a current time, out of the history information; and
controlling a start of a diagnosis of the information recording device on the basis of the selected access record.

2. The information processing apparatus according to claim 1, wherein:
the selecting includes selecting a plurality of access records included within a predetermined time period starting from a time in the predetermined relationship with the current time; and
the controlling includes starting the diagnosis of the information recording device, when all of the selected access records satisfy a predetermined condition.

3. The information processing apparatus according to claim 1, wherein the procedure further comprises:
controlling a halt or restart of the diagnosis of the information recording device on the basis of a newly selected access record, after the diagnosis of the information recording device is started.

4. The information processing apparatus according to claim 1, wherein the procedure further comprises:
controlling an access load that is imposed on the information recording device by the diagnosis thereof, on the basis of a newly selected access record, after the diagnosis of the information recording device is started.

5. The information processing apparatus according to claim 1, wherein the procedure further comprises:
controlling a halt or restart of the diagnosis of the information recording device on the basis of access status detected at the current time, after the diagnosis of the information recording device is started.

6. The information processing apparatus according to claim 1, wherein the procedure further comprises:
controlling access load that is imposed on the information recording device by the diagnosis thereof on the basis of access status detected at the current time, after the diagnosis of the information recording device is started.

7. The information processing apparatus according to claim 1, wherein:
the access status includes a frequency of access made to the information recording device during the predetermined time intervals; and
the start of the diagnosis of the information recording device is controlled on the basis of a comparison between the frequency of access and a preset threshold value.

8. The information processing apparatus according to claim 1, wherein:
the access status includes a data transmission rate at which data is transferred to the information recording device during the predetermined time intervals; and
the start of the diagnosis of the information recording device is controlled on the basis of a comparison between the data transmission rate and a preset threshold value.

9. A non-transitory computer-readable storage medium storing an access control program, the access control program causing a computer to perform a procedure comprising:
detecting access status of an information recording device and forming the detected access status into access records at predetermined time intervals;
generating history information from the access records that have been formed over a predetermined period;
selecting at least one of the access records that has a predetermined relationship with a current time, out of the history information; and
controlling a start of a diagnosis of the information recording device on the basis of the selected access record.

10. The non-transitory computer-readable recording medium according to claim 9, wherein:
the selecting includes selecting a plurality of access records included within a predetermined time period starting from a time in the predetermined relationship with the current time; and
the controlling includes starting the diagnosis of the information recording device, when all of the selected access records satisfy a predetermined condition.

11. The non-transitory computer-readable recording medium according to claim 9, wherein the procedure further comprises:
selecting an access record in the predetermined relationship with the current time as a newly selected access record, from the history information, after the diagnosis of the information recording device is started; and
controlling a halt or restart of the diagnosis of the information recording device on the basis of the newly selected access record.

12. The non-transitory computer-readable recording medium according to claim 9, wherein the procedure further comprises:
selecting an access record in the predetermined relationship with the current time as a newly selected access record, from the history information, after the start of the diagnosis of the information recording device; and
controlling an access load that is imposed on the information recording device by the diagnosis thereof, on the basis of the newly selected access record.

13. The non-transitory computer-readable recording medium according to claim 9, wherein the procedure further comprises:
controlling a halt or a restart of the diagnosis of the information recording device on the basis of the access status detected at the current time, after the diagnosis of the information recording device is started.

14. The non-transitory computer-readable recording medium according to claim 9, wherein the procedure further comprises:
controlling an access load that is imposed on the information recording device by the diagnosis thereof on the basis of the access status detected at the current time, after the diagnosis of the information recording device is started.

15. The non-transitory computer-readable recording medium according to claim 9, wherein:
the access status includes a frequency of access made to the information recording device during the predetermined time intervals; and
the start of the diagnosis of the information recording device is controlled on the basis of a comparison between the access frequency and a preset threshold value.

16. The non-transitory computer-readable recording medium according to claim 9, wherein:
the access status includes a data transmission rate at which data is transferred to the information recording device during the predetermined time intervals; and
the start of the diagnosis of the information recording device is controlled on the basis of a comparison between the data transmission rate and a preset threshold value.

17. An access control method comprising:
detecting, by a computer, access status of an information recording device and forming the detected access status into access records at predetermined time intervals;
generating, by the computer, history information from the access records that have been formed over a predetermined period;
selecting, by the computer, at least one of the access records that has a predetermined relationship with a current time, out of the history information; and
controlling, by the computer, a start of a diagnosis of the information recording device on the basis of the selected access record.

18. The access control method according to claim 17, wherein:
the selecting includes selecting a plurality of access records included within a predetermined time period starting from a time in the predetermined relationship with the current time; and
the controlling includes starting the diagnosis of the information recording device, when all of the selected access records satisfy a predetermined condition.

19. The access control method according to claim 17, further comprising:
selecting an access record in the predetermined relationship with the current time as a newly selected access record, from the history information, after the diagnosis of the information recording device is started; and
controlling a halt or restart of the diagnosis of the information recording device on the basis of the newly selected access record.

20. The access control method according to claim 17, further comprising:
selecting an access record in the predetermined relationship with the current time as a newly selected access record, from the history information, after the diagnosis of the information recording device is started; and
controlling an access load that is imposed on the information recording device by the diagnosis thereof, on the basis of the newly selected access record.
